(19) United States
(12) Patent Application Publication
(10) Pub. No.: US 2026/0354283 A1
(43) Pub. Date: Nov. 5, 2026

(54) SEMICONDUCTOR PACKAGE

(71) Applicant: Murata Manufacturing Co., Ltd., Kyoto-fu (JP)

(72) Inventor: Yoshimasa YOSHIOKA, Nagaokakyo-shi (JP)

(73) Assignee: Murata Manufacturing Co., Ltd., Kyoto-fu (JP)

(21) Appl. No.: 19/720,327

(22) Filed: Jun. 25, 2026

Related U.S. Application Data
(63) Continuation of application No. PCT/JP2024/027079, filed on Jul. 30, 2024.

(30) Foreign Application Priority Data
Dec. 28, 2023 (JP) 2023-222444

(51) Int. Cl. H10W 90/22; H10W 70/09; H10W 70/695; H10W 72/00; H10W 74/15; H10W 90/00; H10W 90/10

(52) U.S. Cl. CPC H10W 90/22; H10W 70/09; H10W 72/823; H10W 74/15; H10W 90/10; H10W 90/401; H10W 90/724; H10W 70/695

(57) ABSTRACT

A semiconductor package, which includes a passive component and an active component, includes a first component layer having a first main surface and a second main surface on an opposite side from the first main surface. The semiconductor package also includes a first wiring layer adjacent to the first component layer in a direction perpendicular to the first main surface. The first component layer includes a first sealing portion containing an inorganic material and an active component inside the first sealing portion. The first component layer also includes a plurality of first via wirings extending inside the first sealing portion in a direction intersecting the first main surface, with end portions thereof exposed from the first sealing portion at the first main surface. The first wiring layer includes a first insulating resin portion and a first wiring portion extending inside the first insulating resin portion.

### CROSS-REFERENCE TO RELATED APPLICATIONS

This application claims benefit of priority to International Patent Application No. PCT/JP2024/027079, filed Jul. 30, 2024, and to Japanese Patent Application No. 2023-222444, filed Dec. 28, 2023, the entire contents of each are incorporated herein by reference.

### BACKGROUND

### Technical Field

The present disclosure relates to a semiconductor package.

### Background Art

An electronic component described in Japanese Unexamined Patent Application Publication No. 2020-178007 includes a core substrate. The core substrate has an opening that extends through the core substrate. The inside of the opening is filled with a magnetic resin. Furthermore, the magnetic resin contains a through hole. A through hole conductor is positioned on the inner side of the through hole. The electronic component also includes an insulating layer and a conductor layer. The insulating layer is located on a main surface of the core substrate. The conductor layer is located on a surface of the insulating layer. The conductor layer, together with the through hole conductor, constitutes an inductor.

### SUMMARY

In electronic components such as the one described in Japanese Unexamined Patent Application Publication No. 2020-178007, an inductor consists of a conductor layer and a through hole conductor. It is difficult to determine whether such an inductor will function correctly until the entire electronic component is manufactured and a current is passed through the electronic component. Therefore, for the electronic component described in Japanese Unexamined Patent Application Publication No. 2020-178007, it is necessary to test whether the inductor functions correctly after the entire electronic component has been manufactured. Although an inductor has been used as an example here, the same problem arises when an electronic component contains a passive component other than an inductor or an active component, as it is difficult to determine whether such a passive or active component will function correctly until the entire electronic component is manufactured.

Accordingly, an aspect of the present disclosure provides a semiconductor package including a passive component and an active component. The semiconductor package includes a first component layer having a first main surface and a second main surface on an opposite side from the first main surface, and a first wiring layer adjacent to the first component layer in a direction perpendicular to the first main surface. The first component layer includes a first sealing portion containing an inorganic material, at least one of the active component located inside the first sealing portion, and a plurality of first via wirings extending inside the first sealing portion in a direction intersecting the first main surface, with end portions thereof exposed from the first sealing portion at the first main surface. The first wiring layer includes a first insulating resin portion and a first wiring portion extending inside the first insulating resin portion. A connection terminal of the active component is exposed from the first sealing portion at a side of the first sealing portion where the second main surface is located.

With the above configuration, a passive component that has passed inspection can be installed, thereby improving reliability.

### BRIEF DESCRIPTION OF THE DRAWINGS

FIG. 1 is a schematic configuration diagram of a semiconductor package of a First Embodiment;

FIG. 2 is an explanatory diagram of a method for manufacturing the semiconductor package of the First Embodiment;

FIG. 3 is an explanatory diagram of the method for manufacturing the semiconductor package of the First Embodiment;

FIG. 4 is an explanatory diagram of the method for manufacturing the semiconductor package of the First Embodiment;

FIG. 5 is an explanatory diagram of the method for manufacturing the semiconductor package of the First Embodiment;

FIG. 6 is an explanatory diagram of the method for manufacturing the semiconductor package of the First Embodiment;

FIG. 7 is an explanatory diagram of the method for manufacturing the semiconductor package of the First Embodiment;

FIG. 8 is an explanatory diagram of the method for manufacturing the semiconductor package of the First Embodiment;

FIG. 9 is an explanatory diagram of the method for manufacturing the semiconductor package of the First Embodiment;

FIG. 10 is an explanatory diagram of the method for manufacturing the semiconductor package of the First Embodiment;

FIG. 11 is an explanatory diagram of the method for manufacturing the semiconductor package of the First Embodiment;

FIG. 12 is a schematic diagram of a semiconductor package of a Second Embodiment;

FIG. 13 is a schematic configuration diagram of a semiconductor package of a modification;

FIG. 14 is a schematic configuration diagram of a semiconductor package of a modification; and

FIG. 15 is a schematic configuration diagram of a semiconductor package of a modification.

### DETAILED DESCRIPTION

Hereinafter, an embodiment of a semiconductor package will be described with reference to the drawings. Note that components may be depicted in an enlarged manner in the drawings for ease of understanding. The dimensional ratios of components may differ from those in the actual product or those in other drawings. Furthermore, some components are designated as first, second, . . . below. These designations are for the sake of convenience only and do not indicate the order of priority of the components. Additionally, the numbers first, second, etc., may be interchanged.

### First Embodiment

### Overall Configuration

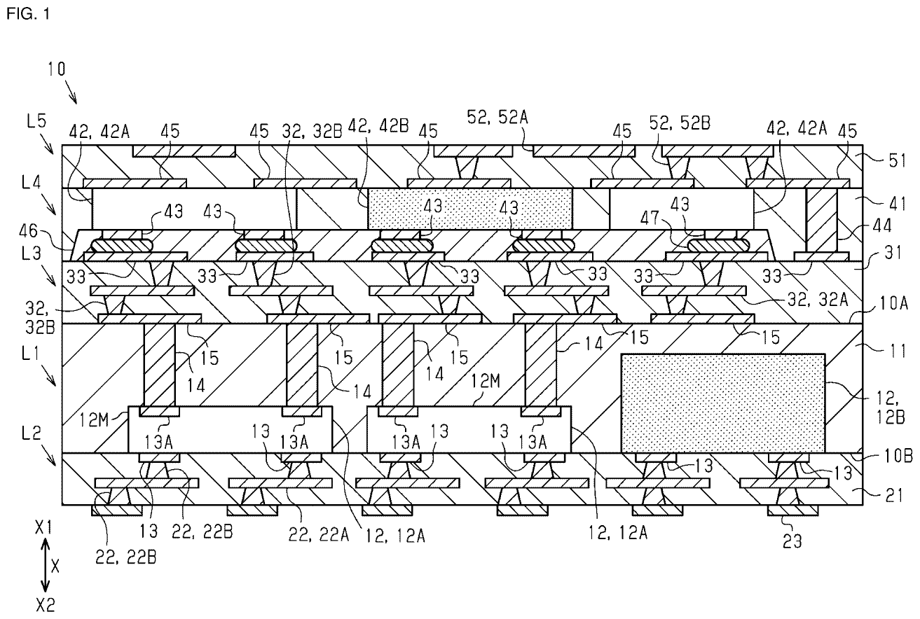

As illustrated in FIG. 1, a semiconductor package 10 includes a first layer L1. The overall outer shape of the first layer L1 is a substantially rectangular parallelepiped shape. The first layer L1 has a first main surface 10A and a second main surface 10B. The first main surface 10A is one of the surfaces having the largest area among the outer surfaces of the first layer L1. When viewed in a direction perpendicular to the first main surface 10A, the first main surface 10A has a rectangular shape. The second main surface 10B is the surface on the opposite side from the first main surface 10A among the outer surfaces of the first layer L1. The second main surface 10B is parallel to the first main surface 10A. When viewed in a direction perpendicular to the second main surface 10B, the second main surface 10B has the same shape as the first main surface 10A.

In the following description, an axis perpendicular to the first main surface 10A is referred to as a first axis X. A specific direction along the first axis X is referred to as a first positive direction X1, and the direction opposite to the first positive direction X1 is referred to as a first negative direction X2. In the First Embodiment, the first positive direction X1 coincides with the direction in which the first main surface 10A faces. The first negative direction X2 coincides with the direction in which the second main surface 10B faces.

The semiconductor package 10 includes a second layer L2, a third layer L3, a fourth layer L4, and a fifth layer L5 stacked on the first layer L1. When viewed in a perspective view along the first axis X, each layer from the first layer L1 to the fifth layer L5 has a rectangular outer shape. The layers of the semiconductor package 10 are arranged in the order of the second layer L2, the first layer L1, the third layer L3, the fourth layer L4, and the fifth layer L5, from the first negative direction X2 side to the first positive direction X1 side.

The first layer L1 includes a first sealing portion 11, a plurality of first electronic components 12, a plurality of first via wirings 14, and a plurality of first component outer terminals 15. The first layer L1 is a first component layer that contains the first electronic components 12.

The outer shape of the first sealing portion 11 is a substantially rectangular parallelepiped shape. The surface of the outer surface of the first sealing portion 11 facing in the first positive direction X1 is the first main surface 10A. The surface of the outer surface of the first sealing portion 11 facing in the first negative direction X2 is the second main surface 10B. The first sealing portion 11 is composed of TEOS (Tetra EthOxy Silane). That is, the first sealing portion 11 contains an inorganic material. SiO₂, TiN, TiO, SiCOH, etc. can be used as the material containing an inorganic material used in the first sealing portion 11.

The first electronic components 12 are either passive or active components. A passive component is an inductor, a resistor, or a capacitor. An active component is an electronic component that performs active work on a current, such as amplification, rectification, or conversion. For example, active components include diodes, transistors, and integrated circuits containing diodes and transistors. Even if an integrated circuit contains an inductor, a resistor, and a capacitor, the integrated circuit will be treated as an active component if it contains at least one active component. In the following description, “electronic component” will refer to either a passive component or an active component.

In the example illustrated in FIG. 1, the first layer L1 contains three first electronic components 12. The three first electronic components 12 include two active components 12A and one passive component 12B. That is, at least one of the first electronic components 12 is an active component 12A. One of the first electronic components 12 is a passive component 12B.

The passive component 12B contains an inorganic material. For example, if the passive component 12B is an inductor, the passive component 12B contains inorganic materials such as Fe, FeSi-based materials, and chromium-zirconium-tantalum alloys. These materials are contained in the core of the inductor. Furthermore, if the passive component 12B is an inductor, the passive component 12B contains inorganic materials such as Cu and Ag. These materials are contained in the wiring of the inductor.

Furthermore, if the passive component 12B is a capacitor, the passive component 12B contains inorganic materials such as SiO₂, SiN, and barium titanate. These materials are contained in the core of the capacitor. Also, if the passive component 12B is a capacitor, the passive component 12B contains materials such as Al and Ni. These materials are contained in the electrodes. In both the case of an inductor and a capacitor, the passive component 12B contains organic materials such as epoxy and polyimide resins.

In the First Embodiment, the volume fraction of inorganic material in the passive component 12B is 80 vol % or more. That is, the volume fraction of inorganic material in the passive component 12B is 50 vol % or more.

Each first electronic component 12 is located inside the first sealing portion 11. Specifically, the three first electronic components 12 are arranged in a direction parallel to the first main surface 10A. Furthermore, each first electronic component 12 is positioned toward the second main surface 10B side within the first layer L1. Specifically, one main surface of each first electronic component 12 is approximately flush with the second main surface 10B of the first layer L1.

Among the first electronic components 12, the maximum dimensions of the two active components 12A in a direction perpendicular to the first main surface 10A are the same. Furthermore, the maximum dimension of the passive component 12B, which is the remaining first electronic component 12, in a direction perpendicular to the first main surface 10A is greater than the maximum dimension of each active component 12A in a direction perpendicular to the first main surface 10A.

Each active component 12A includes a component body 12M, connection terminals 13, and inner terminals 13A. The connection terminals 13 function as outer terminals for connecting the first electronic component 12 to wiring etc. outside the first electronic component 12 In the example illustrated in FIG. 1, each active component 12A has two connection terminals 13 and two inner terminals 13A. The two connection terminals 13 are exposed toward the first negative direction X2 side. Specifically, each connection terminal 13 protrudes from the component body 12M. In addition, each connection terminal 13 is exposed from the first sealing portion 11 on the second main surface 10B side of the first sealing portion 11. Note that each of these connection terminals 13 protrudes from the first sealing portion 11.

On the outer surface of the connection terminals 13 of each first electronic component 12, the volume fraction of Cu is 50 vol % or more. In the First Embodiment, the volume fraction of Cu in the entirety of each connection terminal 13 is 90 vol % or more. Each connection terminal 13 contains small amounts of S, Ni, and O components in addition to the Cu component.

The two inner terminals 13A are exposed from the component body 12M toward the first positive direction X1 side. That is, each inner terminal 13A is exposed from the component body 12M on the opposite side from the connection terminals 13 in a direction perpendicular to the first main surface 10A. In the example illustrated in FIG. 1, the inner terminals 13A do not protrude from the component body 12M. In other words, the end surface of each inner terminal 13A on the first positive direction X1 side is flush with the component body 12M. That is, the amount of protrusion of connection terminals 13 is greater than the amount of protrusion of the inner terminals 13A. The material of each inner terminal 13A is the same as the material of the connection terminals 13.

In the example illustrated in FIG. 1, the passive component 12B, among the first electronic components 12, has two connection terminals 13. The material of these two connection terminals 13 is the same as the material of the connection terminals 13 of the active components 12A. The two connection terminals 13 are exposed toward the first negative direction X2 side. Furthermore, each connection terminal 13 on the first negative direction X2 side is exposed from the first sealing portion 11 on the second main surface 10B side of the first sealing portion 11. Note that each of these connection terminals 13 on the first negative direction X2 side protrudes from the first sealing portion 11. Thus, the connection terminals 13 of each first electronic component 12 are exposed from the first sealing portion 11 only at the second main surface 10B of the first sealing portion 11.

In the example illustrated in FIG. 1, the first layer L1 contains four first via wirings 14. Each first via wiring 14 has a substantially cylindrical shape. Each first via wiring 14 extends within the first sealing portion 11 in a direction intersecting the first main surface 10A. In the First Embodiment, each first via wiring 14 extends in a direction perpendicular to the first main surface 10A. A first end of each first via wiring 14 is connected to the corresponding inner terminal 13A of the corresponding active component 12A. A second end of each first via wiring 14 is exposed from the first sealing portion 11. That is, end portions of the first via wirings 14 are exposed from the first sealing portion 11 at the first main surface 10A.

The first via wirings 14 contain a Cu component. The volume fraction of Cu in the first via wirings 14 is 50 vol % or more. In the First Embodiment, the volume fraction of Cu in first wiring portions 22 is 90 vol % or more.

A plurality of first component outer terminals 15 protrude from the first sealing portion 11. Specifically, a plurality of first component outer terminals 15 are exposed from the first positive direction X1 side of the first sealing portion 11. Each first component outer terminal 15 is connected to the second end of the corresponding first via wiring 14. The material of each first component outer terminal 15 is the same as the material of the first via wirings 14.

The second layer L2 is stacked on the first negative direction X2 side of the first layer L1. In other words, the second layer L2 is directly stacked on the second main surface 10B of the first layer L1. Therefore, the second layer L2 is adjacent to the first component layer in a direction perpendicular to the first main surface 10A.

The second layer L2 includes a first insulating resin portion 21, first wiring portions 22, and a plurality of first wiring outer terminals 23. Therefore, the second layer L2 is a first wiring layer including the first wiring portions 22.

The outer shape of the first insulating resin portion 21 is a substantially rectangular parallelepiped shape. The outer shape of the first insulating resin portion 21 is approximately the same as the outer shape of the second layer L2. The material of the first insulating resin portion 21 is a synthetic resin containing an inorganic filler. The synthetic resin is, for example, an epoxy-based or polyimide-based resin. The first insulating resin portion 21 covers the peripheral surfaces of the connection terminals 13 of the first electronic components 12 that protrude from the first sealing portion 11.

The first wiring portions 22 include a plurality of first columnar wirings 22B extending in a direction intersecting the first main surface 10A, and a plurality of first wirings 22A extending in a direction parallel to the first main surface 10A. The first columnar wirings 22B are connected to the first wirings 22A. These plurality of first columnar wirings 22B and plurality of first wirings 22A are connected to each other. Note that in FIG. 1, only some of the first columnar wirings 22B and some of the first wirings 22A are labeled with reference symbols.

The first wiring portions 22 are connected to the connection terminals 13 of the first electronic components 12. The first wiring portions 22 extend inside the first insulating resin portion 21 in an arbitrary pattern. The material of the first wiring portions 22 is the same as the material of the first via wirings 14. That is, the volume fraction of Cu in the first wiring portions 22 is 50 vol % or more.

A plurality of first wiring outer terminals 23 protrude from the first insulating resin portion 21. Specifically, a plurality of first wiring outer terminals 23 are exposed from the first negative direction X2 side of the first insulating resin portion 21. The material of each first wiring outer terminal 23 has a three-layer structure consisting of, from the first positive direction X1 side, a layer having Cu as a main component, a layer having Ni as a main component, and a layer having Au as a main component. These first wiring outer terminals 23 function as outer terminals when mounting the semiconductor package 10 on a substrate or the like. Note that in FIG. 1, only some of the first wiring outer terminals 23 are labeled with reference symbols.

The third layer L3 is stacked on the first positive direction X1 side of the first layer L1. In other words, the third layer L3 is stacked on the first main surface 10A of the first layer L1. That is, the third layer L3 is adjacent to the first component layer in a direction perpendicular to the first main surface 10A.

The third layer L3 includes a second insulating resin portion 31, second wiring portions 32, and a plurality of second wiring outer terminals 33. The third layer L3 is a second wiring layer including the second wiring portions 32.

The outer shape of the second insulating resin portion 31 is a substantially rectangular parallelepiped shape. The outer shape of the second insulating resin portion 31 is approximately the same as the outer shape of the third layer L3. The material of the second insulating resin portion 31 is a synthetic resin containing an inorganic filler. The second insulating resin portion 31 covers the peripheral surfaces of the first component outer terminals 15.

The second wiring portions 32 include a plurality of second wirings 32A extending in a direction parallel to the first main surface 10A, and a plurality of second columnar wirings 32B extending in a direction intersecting the first main surface 10A. The second columnar wirings 32B are connected to the second wirings 32A. These plurality of second columnar wirings 32B and plurality of second wirings 32A are connected to each other. Note that in FIG. 1, only some of the second columnar wirings 32B and some of the second wirings 32A are labeled with reference symbols.

The second wiring portions 32 are connected to the first component outer terminals 15. That is, the second wiring portions 32 are connected to the first via wirings 14 in the first layer L1 via the first component outer terminals 15. In other words, the second ends of the first via wirings 14 are connected to the second wiring portions 32 in the second wiring layer.

The second wiring portions 32 extend within the second insulating resin portion 31 in an arbitrary pattern. The material of the second wiring portions 32 is the same as that of the first wiring portions 22. That is, the volume fraction of Cu in the second wiring portions 32 is 50 vol % or more.

A plurality of second wiring outer terminals 33 protrude from the second insulating resin portion 31. Specifically, a plurality of second wiring outer terminals 33 are exposed from the first positive direction X1 side of the second insulating resin portion 31. The material of each second wiring outer terminal 33 is the same as the material of the first component outer terminals 15.

The fourth layer L4 is stacked on the first positive direction X1 side of the third layer L3. The fourth layer L4 includes a second sealing portion 41, a plurality of second electronic components 42, a second via wiring 44, a plurality of second component outer terminals 45, a plurality of connection portions 47, and an underfill 46. Note that the fourth layer L4 is a second component layer including the second electronic components 42.

The outer shape of the second sealing portion 41 is a substantially rectangular parallelepiped shape. The outer shape of the second sealing portion 41 is approximately the same as the outer shape of the fourth layer L4. The material of the second sealing portion 41 is a synthetic resin containing an inorganic filler.

In the example illustrated in FIG. 1, the fourth layer L4 includes three second electronic components 42. The second electronic components 42 include two active components 42A and one passive component 42B. That is, at least one of the second electronic components 42 is an active component 42A. One of the second electronic components 42 is a passive component 42B. The volume fraction of inorganic material in the passive component 42B is 80 vol % or more.

Each second electronic component 42 is located inside the second sealing portion 41. Specifically, the three second electronic components 42 are arranged in a direction parallel to the first main surface 10A.

Each second electronic component 42 has connection terminals 43. The connection terminals 43 function as outer terminals for connecting the second electronic components 42 to wiring etc. outside the second electronic component 42.

In the example illustrated in FIG. 1, each second electronic component 42 has two connection terminals 43. Each connection terminal 43 is exposed toward the first negative direction X2 side. These connection terminals 43 are not covered by the second insulating resin portion 31. The material of the connection terminals 43 of each second electronic component 42 is the same as the material of the connection terminals 43 of the first electronic components 12.

The second via wiring 44 is substantially cylindrical in shape. The second via wiring 44 extends inside the second sealing portion 41 in a direction intersecting the first main surface 10A. In the First Embodiment, the second via wiring 44 extends in a direction perpendicular to the first main surface 10A. A first end of the second via wiring 44 is connected to one of the second wiring outer terminals 33. A second end of the second via wiring 44 is exposed from the second sealing portion 41. That is, an end portion of the second via wiring 44 is exposed from the second sealing portion 41 at the surface on the first positive direction X1 side. The material of the second via wiring 44 is the same as the material of the first via wirings 14.

A plurality of second component outer terminals 45 protrude from the second sealing portion 41. Specifically, a plurality of second component outer terminals 45 are exposed from the first positive direction X1 side of the second sealing portion 41. One of the second component outer terminals 45 is connected to the second end of the second via wiring 44. The material of each second component outer terminal 45 is the same as the material of the first component outer terminals 15.

The second wiring outer terminals 33 that are not connected to the second via wiring 44 are connected to the connection terminals 43 of the second electronic components 42 via the connection portions 47. The connection portions 47 are composed of a conductive material such as solder. There are as many connection portions 47 as there are second wiring outer terminals 33. Each connection portion 47 is applied to the corresponding second wiring outer terminal 33. That is, each connection portion 47 covers the surface of the corresponding second wiring outer terminal 33 on the first positive direction X1 side.

The underfill 46 is located inside the second sealing portion 41. The underfill 46 is located in a region from the first positive direction X1 side of the second insulating resin portion 31 to the edges of the connection terminals 43 on the first positive direction X1 side. That is, the underfill 46 covers the second wiring outer terminals 33, the connection portions 47, and the peripheral surfaces of the connection terminals 43. The material constituting the underfill 46 is, for example, epoxy resin. However, the material of the underfill 46 is not limited to epoxy resin, and may also be a polyimide resin, a liquid crystal polymer resin, an acrylic resin, a phenolic resin, or a combination such resins. Furthermore, the underfill 46 may contain an inorganic filler such as silica filler.

The fifth layer L5 is stacked on the first positive direction X1 side of the fourth layer L4. The fifth layer L5 includes a third insulating resin portion 51 and third wiring portions 52. The fifth layer L5 is a third wiring layer including the third wiring portions 52.

The outer shape of the third insulating resin portion 51 is a substantially rectangular parallelepiped shape. The outer shape of the third insulating resin portion 51 is approximately the same as that of the fifth layer L5. The material of the third insulating resin portion 51 is the same as that of the first insulating resin portion 21. The second component outer terminals 45 are embedded in the first negative direction X2 side of the third insulating resin portion 51.

The third wiring portions 52 include a plurality of third columnar wirings 52B extending in a direction intersecting the first main surface 10A, and a plurality of third wirings 52A extending in a direction parallel to the first main surface 10A. The third columnar wirings 52B are connected to the third wirings 52A. Note that in FIG. 1, only some of the third columnar wirings 52B and some of the third wirings 52A are labeled with reference symbols.

The third wiring portions 52 are connected to the second component outer terminals 45. The third wiring portions 52 extend inside the third insulating resin portion 51 in an arbitrary pattern. The material of the third wiring portions 52 is the same as the material of the first wiring portions 22. That is, the volume fraction of Cu in the third wiring portions 52 is 50 vol % or more.

### Method for Manufacturing Semiconductor Package

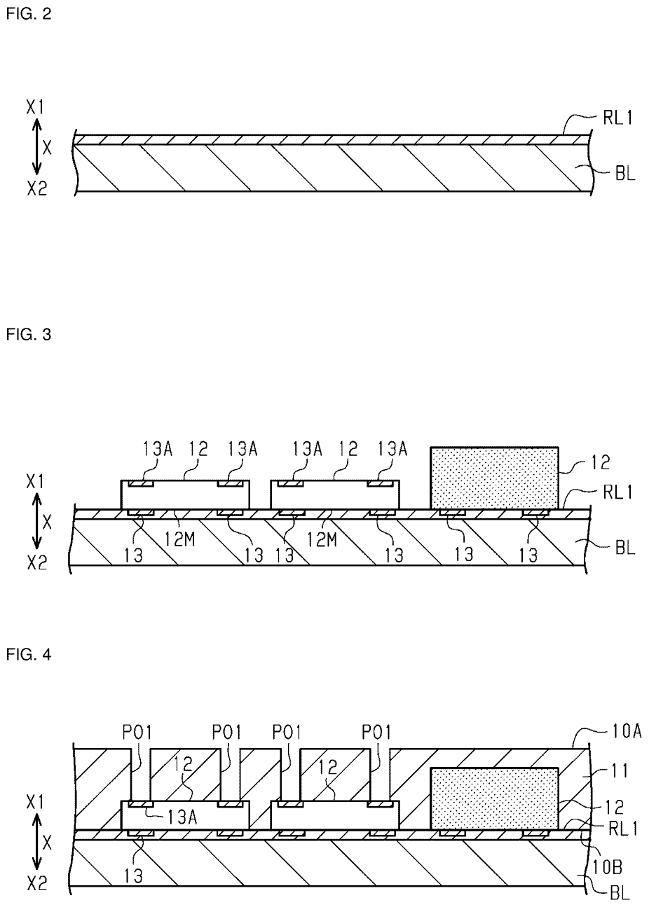

A method for manufacturing the semiconductor package 10 will be described. Note that in FIGS. 2 to 11, only some components may be labeled with reference symbols.

As illustrated in FIG. 2, first, a plate-shaped base substrate BL is prepared. The material of the base substrate BL is silicon. In the following description, it is assumed that the main surfaces of the base substrate BL are perpendicular to the first axis X. When viewed in the first negative direction X2, the base substrate BL has a rectangular shape, for example. The dimensions of the sides of the base substrate BL are selected such that a plurality of semiconductor packages 10 can be accommodated therein. Next, a first release layer RL1 is applied to the entire first positive direction X1 side, i.e., top surface, of the base substrate BL. The first release layer RL1 is a sheet-like member with adhesive properties, such as infrared-curable resin tape, an acrylic resin adhesive, or a polyimide adhesive.

Next, as illustrated in FIG. 3, the first electronic components 12 are disposed on the first release layer RL1. Specifically, the first electronic components 12 are disposed with their connection terminals 13 facing the first release layer RL1.

Next, as illustrated in FIG. 4, the first sealing portion 11 is formed. Specifically, first, an insulator is formed from the first positive direction X1 side of each first electronic component 12 and the first release layer RL1 using a known technique such as a CVD method. The material of the insulator is TEOS. Next, first through holes PO1 are formed in the insulator using a known technique such as the Bosch process. The first through holes PO1 are formed at positions that overlap the inner terminals 13A of the first electronic components 12 when viewed in the first negative direction X2.

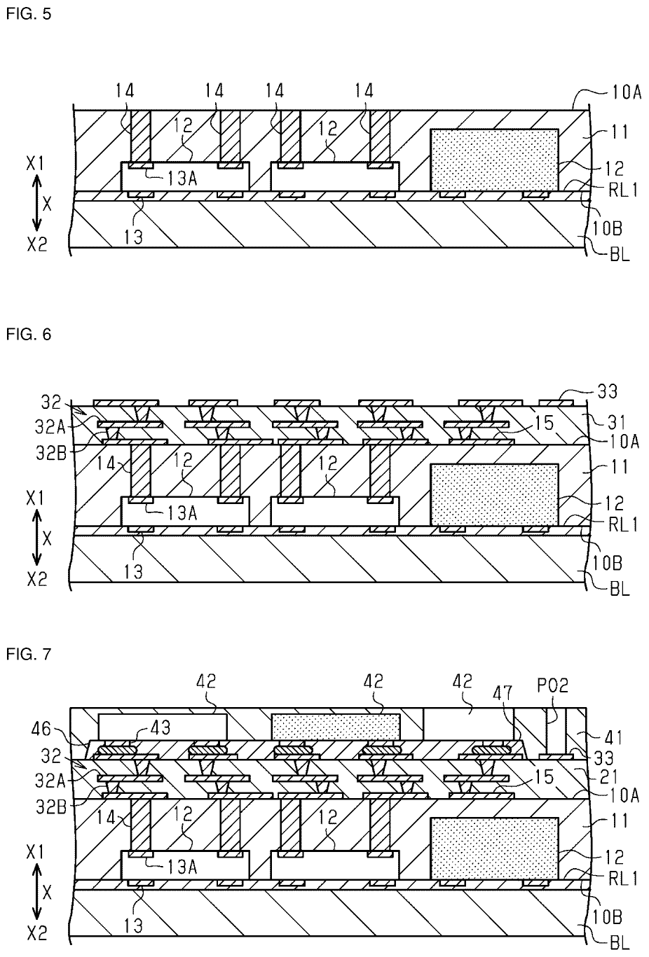

Next, as illustrated in FIG. 5, the first via wirings 14 are formed in the first through holes PO1. The first via wirings 14 are formed using a known technique such as a via-fill method. Although not illustrated, a seed layer composed of Cu is formed during the process of forming the first via wirings 14.

Next, as illustrated in FIG. 6, the second insulating resin portion 31, the second wiring portions 32, and the second wiring outer terminals 33 are formed on the first positive direction X1 side of the first sealing portion 11. The second insulating resin portion 31 is formed by photolithography. The second wiring portions 32 and the second wiring outer terminals 33 are formed using a known technique such as the semi-additive process. In this step, the second wiring outer terminals 33 may be subjected to surface treatment using a known method such as electroless plating or electrolytic plating.

Next, as illustrated in FIG. 7, the second electronic components 42 are mounted. Specifically, the terminals of the second electronic components 42 are soldered to the second wiring outer terminals 33. The solder portions after connection become the connection portions 47. In addition, epoxy resin is filled between the second insulating resin portion 31 and the second electronic components 42. As a result, the underfill 46 is formed.

Next, the second sealing portion 41 is formed. Specifically, an insulator is stacked from the first positive direction X1 side of the second electronic components 42 and the second insulating resin portion 31. The material of the insulator is an organic resin containing an inorganic filler. Next, the insulator is irradiated with a laser from the first positive direction X1 side. Specifically, the laser is radiated onto a portion of the insulator on the first positive direction X1 side of the second wiring outer terminal 33 that is not connected to the second electronic components 42, and where the second via wiring 44 will be formed. In this way, the insulator is processed to form a second through hole PO2.

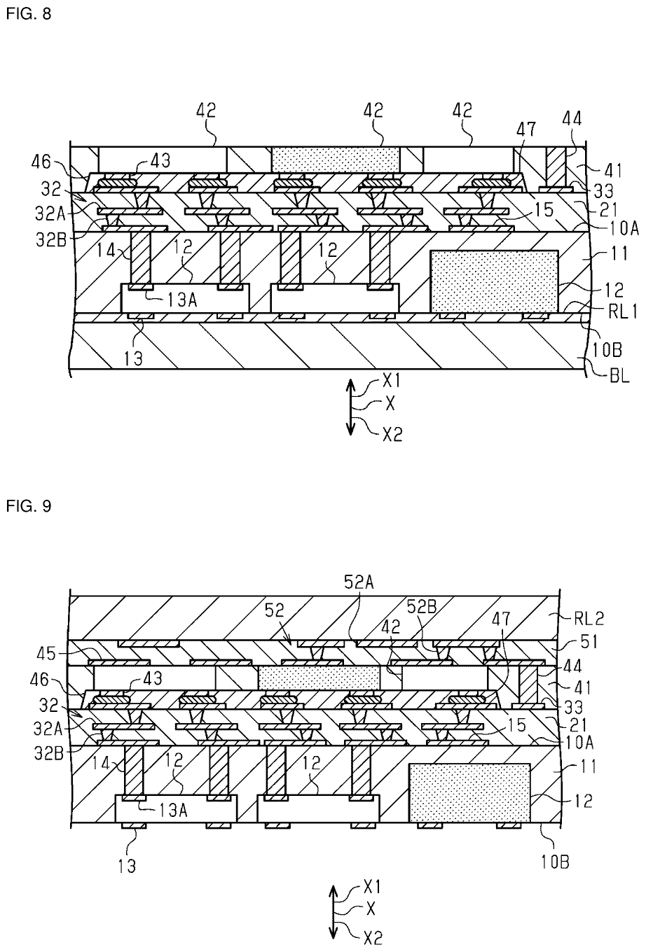

Next, as illustrated in FIG. 8, the second via wiring 44 is formed in the second through hole PO2. The second via wiring 44 is formed using a known technique such as a via-fill method. Although not illustrated, a seed layer composed of Cu is formed during the process of forming the second via wiring 44. Then, a portion of the second sealing portion 41 and the second via wiring 44 on the first positive direction X1 side is ground down to achieve the desired size.

Next, as illustrated in FIG. 9, the third insulating resin portion 51, the third wiring portions 52, and the second component outer terminals 45 are formed. The third insulating resin portion 51 is formed by photolithography. The third wiring portions 52 and the second component outer terminals 45 are formed using known techniques such as the semi-additive process. Next, the first release layer RL1 is removed by cutting. Furthermore, a second release layer RL2 is formed on the first positive direction X1 side of the third insulating resin portion 51. The second release layer RL2 is formed to cover the entirety of the third insulating resin portion 51. The material of the second release layer RL2 is the same as the material of the first release layer RL1.

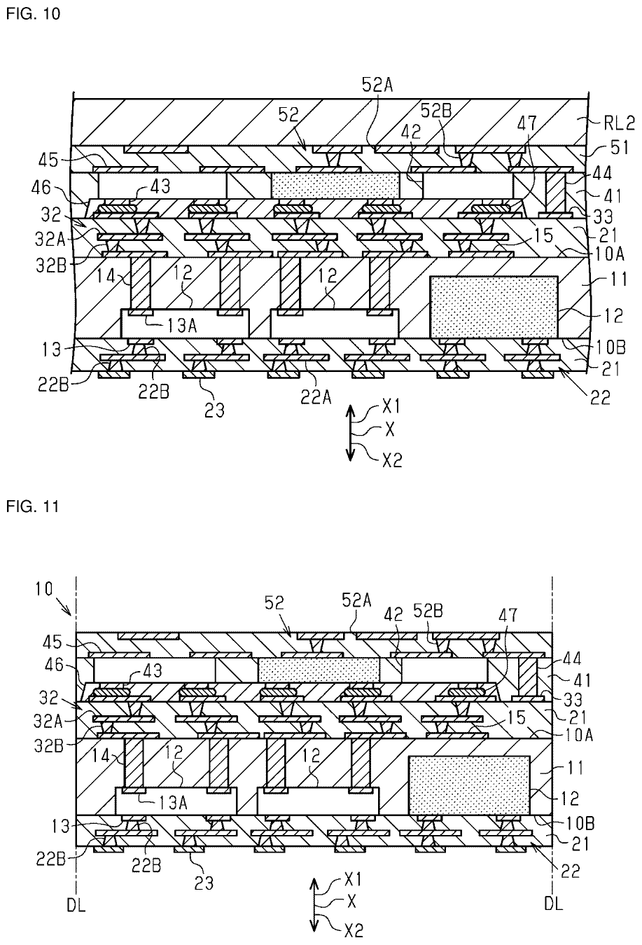

Next, as illustrated in FIG. 10, the first insulating resin portion 21, the first wiring portions 22, and the first wiring outer terminals 23 are formed on the first negative direction X2 side of the first sealing portion 11. The first insulating resin portion 21 is formed by photolithography. Parts of the first wiring portions 22 and the first wiring outer terminals 23 are formed by known techniques such as the semi-additive process. Furthermore, a layer having Ni as a main component and a layer having Au as a main component are formed on parts of the formed first wiring outer terminals 23 using a known method such as electroless plating or electrolytic plating. Thus, the formation of the first wiring outer terminals 23 is completed.

Next, as illustrated in FIG. 11, the body is diced along break lines DL to obtain the desired size for the semiconductor package 10. Then, the second release layer RL2 is removed by cutting.

### Effects of First Embodiment

(1-1) According to the First Embodiment described above, the semiconductor package 10 includes the active components 12A and the passive component 12B. These active components 12A and passive component 12B are mounted during the process of forming the semiconductor package 10. That is, with the above configuration, only the active components 12A and the passive component 12B that have been determined to be non-defective in advance can be used. Therefore, it is not necessarily required to perform tests on these active components 12A and passive component 12B to determine whether they are functioning correctly after the entire semiconductor package 10 has been formed. With such a configuration, the yield for the semiconductor package 10 can be increased.

(1-2) In the First Embodiment described above, the second layer L2, which is the first wiring layer, is stacked on the second main surface 10B of the first layer L1, which is the first component layer. By stacking the second layer L2 on the first layer L1, the second main surface 10B of the first layer L1 is covered by the second layer L2. With this configuration, the second layer L2 can mitigate external shocks acting on the active components 12A and the passive component 12B contained in the first layer L1.

Furthermore, in the First Embodiment described above, the third layer L3, which is the second wiring layer, is stacked on the first main surface 10A of the first layer L1, which is the first component layer. This configuration allows the impact of shocks on the active components 12A and the passive component 12B to be further suppressed.

(1-3) In the First Embodiment described above, the first ends of the first via wirings 14 are connected to the first electronic components 12. The second ends of the first via wirings 14 are connected to the first wiring portions 22 within the first wiring layer. In other words, the first via wirings 14 connect the first electronic components 12 and the first wiring portions 22 to each other. With this configuration, current can be directly supplied to the first electronic components 12 from a direction perpendicular to the first main surface 10A through the first via wirings 14. In other words, the first electronic components 12 and the first wiring portions 22 can be connected without requiring, for example, wiring extending parallel to the first main surface 10A and vias extending in a direction intersecting the first main surface 10A within the first layer L1.

(1-4) In the First Embodiment described above, the volume fraction of Cu at the outer surfaces of the connection terminals 13 of the first electronic components 12 is 50 vol % or more. Also, the volume fraction of Cu in the first wiring portions 22 is 50 vol % or more. In the First Embodiment described above, the material of the first via wirings 14 connecting the first wiring portions 22 and the connection terminals 13 is the same as the material of the first wiring portions 22, and contains 50 vol % or more of Cu. That is, since the materials of the interfaces between the connection terminals 13 and the first via wirings 14 are the same, the connection terminals 13 and the first via wirings 14 are easily integrated. Therefore, the connection strength between the connection terminals 13 and the first via wirings 14 can be improved. Similarly, since the materials of the interfaces between the first wiring portions 22 and the first via wirings 14 are the same, the connection strength between the first wiring portions 22 and the first via wirings 14 can be improved. Therefore, the electrical connections between the first electronic components 12 and the first wiring portions 22 are easily maintained.

(1-5) In the First Embodiment described above, the passive component 12B contains an inorganic material. The volume fraction of the inorganic material in the passive component 12B is 50 vol % or more. Furthermore, the first sealing portion 11 covering the peripheral surface of the passive component 12B also contains an inorganic material. In other words, with this configuration, the difference between the thermal expansion coefficient of the passive component 12B and the thermal expansion coefficient of the first sealing portion 11 is not very large. With such a relationship between the thermal expansion coefficients, the amount of deformation of these components due to changes in temperature does not diverge significantly, and therefore warping in the first layer L1 due to thermal deformation can be suppressed.

(1-6) In the First Embodiment described above, the maximum dimension of the passive component 12B in a direction perpendicular to the first main surface 10A is greater than the maximum dimension of each active component 12A in a direction perpendicular to the first main surface 10A. That is, the thickness dimension of the passive component 12B is comparatively large. Therefore, for example, if the passive component 12B is an inductor, it is easy to design the passive component 12B such that the desired inductance is obtained. Similarly, if the passive component 12B is a capacitor, it is easy to design the passive component 12B such that the desired capacitance is obtained.

(1-7) In the First Embodiment described above, the amount of protrusion of the connection terminals 13 of the active components 12A of the first electronic component 12 is greater than the amount of protrusion of the inner terminals 13A. The larger amount of protrusion of the connection terminals 13 allows the connection terminals 13 to be used as a positioning tool when disposing the active components 12A in process of manufacturing the semiconductor package 10. In addition, the connection terminals 13 increase the surface area of the surface of the first layer L1 facing in the first negative direction X2, thereby improving adhesion with the second layer L2. Furthermore, the relatively small amount of protrusion of the inner terminals 13A helps prevent the dimension of the active components 12A themselves in a direction perpendicular to the first main surface 10A from becoming larger.

### Second Embodiment

### Overall Configuration

A Second Embodiment of a semiconductor package will be described below.

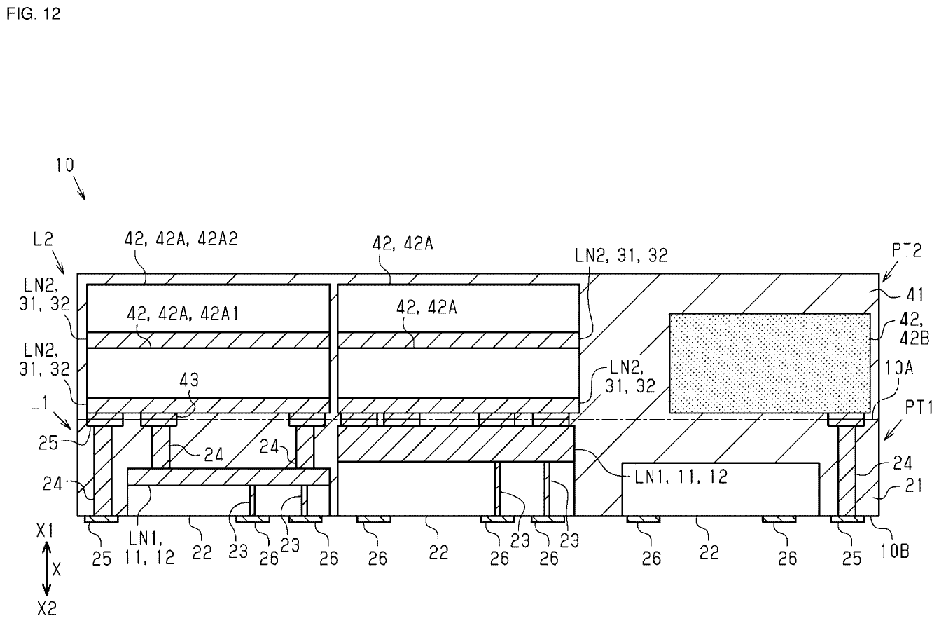

As illustrated in FIG. 12, the semiconductor package 10 of the Second Embodiment includes a first layer L1 and a second layer L2. The first layer L1 has a first main surface 10A and a second main surface 10B. The first main surface 10A and the second main surface 10B are substantially the same as in the First Embodiment. The first axis X, the first positive direction X1, and the first negative direction X2 are also handled in substantially the same way as in the First Embodiment.

The first layer L1 includes a first component layer PT1 and two first wiring layers LN1. In the Second Embodiment, each first wiring layer LN1, which is a separate layer from the first component layer PT1, is embedded inside the first component layer PT1.

The first component layer PT1 includes a first sealing portion 21, a plurality of first electronic components 22, a plurality of first via wirings 24, and a plurality of first component outer terminals 25.

The outer shape of the first sealing portion 21 is a substantially rectangular parallelepiped shape. The two first wiring layers LN1 described above are located inside the first sealing portion 21. That is, the first wiring layers LN1 are adjacent to the first sealing portion 21 or the first electronic components 22, which are part of the first component layer PT1, in a direction perpendicular to the first main surface 10A. The material of the first sealing portion 21 is the same as in the First Embodiment. That is, the first sealing portion 21 contains an inorganic material.

In the example illustrated in FIG. 12, the first layer L1 contains three first electronic components 22. All three first electronic components 22 are active components. In other words, at least one of the first electronic components 22 is an active component.

Each first electronic component 22 is located inside the first sealing portion 21. Specifically, the three first electronic components 22 are arranged in a direction parallel to the first main surface 10A. Furthermore, each first electronic component 22 is positioned toward the second main surface 10B within the first layer L1. Specifically, one main surface of each first electronic component 22 is approximately flush with the second main surface 10B of the first layer L1.

Two of the three first electronic components 22 are adjacent to different first wiring layers LN1. Specifically, the first wiring layers LN1 are stacked on the first positive direction X1 side of the two first electronic components 22. Note that each first wiring layer LN1 is not electrically connected to the other first wiring layer LN1 within the first layer L1.

Each first electronic component 22 has connection terminals 26. The connection terminals 26 function as outer terminals of the first electronic component 22 for connecting the first electronic component 22 to external wiring, etc. In the example illustrated in FIG. 12, each first electronic component 22 has a plurality of connection terminals 26. Each connection terminal 26 is exposed toward the first negative direction X2 side. Each connection terminal 26 is also exposed from the first sealing portion 21 on the second main surface 10B side of the first sealing portion 21. Each connection terminal 26 protrudes from the first sealing portion 21. The volume fraction of Cu at the outer surface of each connection terminal 26 is 50 vol % or more. The material of the connection terminals 26 in the Second Embodiment is substantially the same as in the First Embodiment.

Each first wiring layer LN1 includes a first wiring portion 12 and a first insulating resin portion 11. Note that in FIG. 12, the first wiring portions 12 and the first insulating resin portions 11 inside the first wiring layers LN1 are not illustrated. The first wiring portions 12 and the first insulating resin portions 11 have substantially the same configuration as in the First Embodiment. That is, the outer shape of each first insulating resin portion 11 is a substantially rectangular parallelepiped shape. However, the dimension of each first insulating resin portion 11 in a direction parallel to the first main surface 10A is smaller than the dimension of the first layer L1 in a direction parallel to the first main surface 10A. Also, the dimension of each first insulating resin portion 11 in a direction perpendicular to the first main surface 10A is smaller than the dimension of the first layer L1 in a direction perpendicular to the first main surface 10A. The material of each first insulating resin portion 11 is a synthetic resin containing an inorganic filler.

Each first wiring portion 12 extends inside the corresponding first insulating resin portion 11 in an arbitrary pattern. The material of each first wiring portion 12 is the same as the material of the first wiring portions 12 in the First Embodiment. That is, the volume fraction of Cu in the first wiring portions 12 is 50 vol % or more.

The two first electronic components 22 adjacent to the first wiring layers LN1 include through wirings 23. That is, one or more selected from among the active components include the through wirings 23. Each active component includes two through wirings 23. Each through wiring 23 has a substantially cylindrical shape. Each through wiring 23 penetrates through the active component in a direction perpendicular to the first main surface 10A. The end of each through wiring 23 on the first positive direction X1 side is connected to the corresponding first wiring portion 12 of the corresponding first wiring layer LN1. The end of each through wiring 23 on the first negative direction X2 side is connected to the corresponding connection terminal 26.

In the cross-section illustrated in FIG. 12, the first component layer PT1 includes four first via wirings 24. Each first via wiring 24 has a substantially cylindrical shape. The diameter of each first via wiring 24 is greater than the diameter of each through wiring 23. In other words, the maximum dimension of the through wirings 23 in a direction parallel to the first main surface 10A is smaller than the maximum dimension of the first via wirings 24 in a direction parallel to the first main surface 10A. Each first via wiring 24 extends in a direction intersecting the first main surface 10A inside the first sealing portion 21. In the Second Embodiment, each first via wiring 24 extends in a direction perpendicular to the first main surface 10A.

Two of the four first via wirings 24 extend from the first wiring layer LN1. Specifically, a first end of each first via wiring 24 on the first negative direction X2 side is connected to the corresponding first wiring portion 12 of the corresponding first wiring layer LN1. A second end of each first via wiring 24 on the first positive direction X1 side is exposed from the first sealing portion 21 on the first main surface 10A side.

Furthermore, the first ends of the remaining two first via wirings 24 on the first negative direction X2 side are exposed from the first sealing portion 21 on the second main surface 10B side. Also, the second ends of these two first via wirings 24 on the first positive direction X1 side are exposed from the first sealing portion 21 on the first main surface 10A side. In other words, the end portions of the four first via wirings 24 in the Second Embodiment are exposed from the first sealing portion 21 on the first main surface 10A side.

The first via wirings 24 contain a Cu component. The volume fraction of Cu in the first via wirings 24 is 50 vol % or more. In the Second Embodiment, similarly to the First Embodiment, the volume fraction of Cu in the first via wirings 24 is 90 vol % or more.

In the cross-section illustrated in FIG. 12, the first layer L1 includes 10 first component outer terminals 25. Note that the first layer L1 may also include other first component outer terminals 25 not illustrated in the cross-section in FIG. 12. Two of these first component outer terminals 25 protrude from the first negative direction X2 side of the first sealing portion 21. Each of these first component outer terminals 25 is connected to the first end of the corresponding first via wiring 24 exposed from the first sealing portion 21 on the second main surface 10B side. The material of these ten first component outer terminals 25 is the same as the material of the connection terminals 26.

Furthermore, the remaining eight of the first component outer terminals 25 illustrated in the cross-section in FIG. 12 are exposed on the first positive direction X1 side of the first sealing portion 21. The peripheral surfaces of these eight first component outer terminals 25 are covered by the first sealing portion 21. Four of these first component outer terminals 25 are connected to the first positive direction X1 ends of the corresponding first via wirings 24. The remaining four first component outer terminals 25 are directly stacked on the first positive direction X1 side of the corresponding first wiring layer LN1. These first component outer terminals 25 are electrically connected to the first wiring portions 12 in the first wiring layer LN1. The material of these eight first component outer terminals 25 is the same as the material of the first wiring portions 12. Note that in FIG. 12, only some of the first component outer terminals 25 are labeled with reference symbols.

The second layer L2 is directly stacked to the first positive direction X1 side of the first layer L1. The second layer L2 includes a second component layer PT2 and four second wiring layers LN2. Similarly to the first layer L1 described above, in the second layer L2, the second wiring layers LN2, which are separate layers from the second component layer PT2, are embedded inside the second component layer PT2.

The second component layer PT2 includes a second sealing portion 41, a plurality of second electronic components 42, and a plurality of second component outer terminals 43.

The outer shape of the second sealing portion 41 is a substantially rectangular parallelepiped shape. The four second wiring layers LN2 described above are located inside the second sealing portion 41. That is, the second wiring layers LN2 are adjacent to the second sealing portion 41 or the second electronic components 42, which are part of the second component layer PT2, in a direction perpendicular to the first main surface 10A. The material of the second sealing portion 41 is the same as the material of the first sealing portion 21. That is, the second sealing portion 41 contains an inorganic material.

In the example illustrated in FIG. 12, the second layer L2 contains five second electronic components 42. Four of the five second electronic components 42 are active components 42A. The one remaining second electronic component 42 is a passive component 42B. That is, at least one of the second electronic components 42 is an active component 42A. At least one of the second electronic components 42 is a passive component 42B.

Two of the four active components 42A are arranged in a direction parallel to the first main surface 10A. A second wiring layer LN2 is stacked on the first negative direction X2 side of each of these two active components 42A. Furthermore, a second wiring layer LN2 and other active components 42A are stacked on the first positive direction X1 side of the two active components 42A. Thus, these elements form a multilayer body consisting of a total of four elements, stacked in the order of the second wiring layer LN2, the active component 42A, the second wiring layer LN2, and the active component 42A toward the first positive direction X1. A pair of these multilayer bodies are arranged in a direction parallel to the first main surface 10A. In addition, adjacent second wiring layers LN2 and active components 42A are electrically connected to each other. However, the individual second wiring layers LN2 are not electrically connected to each other within the second layer L2.

Here, two active components 42A in one of multilayer bodies stacked in a direction along the first axis X are referred to as a first active component 42A1 and a second active component 42A2, respectively. The first active component 42A1 is located on the first negative direction X2 side relative to the second active component 42A2. The first active component 42A1 and the second active component 42A2 are stacked relative to the first component layer PT1 in a direction perpendicular to the first main surface 10A. Furthermore, there are no electronic components between the first active component 42A1 and the first component layer PT1. That is, the first active component 42A1 and the second active component 42A2 are stacked relative to the first component layer PT1 in a direction perpendicular to the first main surface 10A without any other electronic components therebetween. The maximum dimension of the first active component 42A1 in a direction perpendicular to the first main surface 10A is the same as the maximum dimension of the second active component 42A2 in a direction perpendicular to the first main surface 10A. The thickness dimensions of the active components 42A are the same.

The passive component 42B among the second electronic components 42 is positioned in a direction parallel to the first main surface 10A with respect to the pair of multilayer bodies in which the active components 42A and the second wiring layers LN2 are stacked. The passive component 42B contains an inorganic material. The volume fraction of inorganic material in the passive component 42B is 80 vol % or more.

The maximum dimension of the passive component 42B in a direction perpendicular to the first main surface 10A is greater than the sum of the maximum dimension of the first active component 42A1 in a direction perpendicular to the first main surface 10A and the maximum dimension of the second active component 42A2 in a direction perpendicular to the first main surface 10A.

Each of the second wiring layers LN2 described above includes the second wiring portions 32 and the second insulating resin portion 31. Note that in FIG. 12, the second wiring portions 32 and the second insulating resin portion 31 inside each second wiring layer LN2 are not illustrated. The second wiring portions 32 and the second insulating resin portion 31 have the same configuration as those in the first wiring layers LN1 described above. That is, the outer shape of each second insulating resin portion 31 is a substantially rectangular parallelepiped shape. However, since the second wiring layers LN2 are embedded inside the second component layer PT2, the dimension of each second insulating resin portion 31 in a direction parallel to the first main surface 10A is smaller than the dimension of the second layer L2 in a direction parallel to the first main surface 10A. Also, the dimension of each second insulating resin portion 31 in a direction perpendicular to the first main surface 10A is smaller than the dimension of the second layer L2 in a direction perpendicular to the first main surface 10A. The material of each second insulating resin portion 31 is a synthetic resin containing an inorganic filler.

Each second wiring portion 32 extends inside the corresponding second insulating resin portion 31 in an arbitrary pattern. The material of each second wiring portion 32 is the same as the material of the second wiring portions 32. That is, the volume fraction of Cu in the second wiring portions 32 is 50 vol % or more.

In the cross-section illustrated in FIG. 12, the second layer L2 has eight second component outer terminals 43. Note that the second layer L2 may also have other second component outer terminals 43 not illustrated in the cross-section in FIG. 12. Seven of the second component outer terminals 43 in the cross-section illustrated in FIG. 12 are directly stacked on the first negative direction X2 side of the second wiring layers LN2. These seven second component outer terminals 43 are electrically connected to the second wiring layers LN2. The remaining second component outer terminal 43 in the cross-section illustrated in FIG. 12 is directly stacked on the first negative direction X2 side of the passive component 42B among the second electronic components 42.

The peripheral surfaces of the eight second component outer terminals 43 in the cross-section illustrated in FIG. 12 are covered by the second sealing portion 41. Furthermore, the eight second component outer terminals 43 are exposed at the first negative direction X2 side of the second sealing portion 41. That is, each second component outer terminal 43 is exposed from the surface of the second sealing portion 41 on the side where the first component layer PT1 is located.

Furthermore, as described above, eight of the first component outer terminals 25 in the cross-section illustrated in FIG. 12 are exposed at the first positive direction X1 side of the first sealing portion 21. That is, the first component outer terminals 25 are exposed from the surface of the first sealing portion 21 on the side where the second component layer PT2 is located. The first component outer terminals 25 are connected to the second component outer terminals 43 without any other members therebetween. Similarly, the first sealing portion 21 facing in the first positive direction X1 is in contact with the second sealing portion 41 facing in the first negative direction X2 without any other members therebetween.

Each component of the first layer L1 and the second layer L2 contains an inorganic material. In the Second Embodiment, the semiconductor package 10 as a whole is almost entirely composed of an inorganic material. Specifically, the volume fraction of inorganic material in the semiconductor package 10 as a whole is 90 vol % or more.

### Effects of Second Embodiment

(2-1) According to the Second Embodiment described above, the first component layer PT1 contains the first electronic components 22. The first electronic components 22 are mounted during the process of forming the semiconductor package 10. That is, with the above configuration, it is possible to used only the first electronic components 22 that have been determined to be non-defective in advance. Therefore, it is not necessarily required to perform tests on these first electronic components 22 to determine whether or not they are functioning correctly after the entire semiconductor package 10 has been formed. With such a configuration, the yield for the semiconductor package 10 can be increased.

(2-2) In the Second Embodiment, one or more components selected from among the first electronic components 22 include the through wirings 23. The through wirings 23 are connected to the first wiring portions 12. With this configuration, current can be passed along the through wirings 23 in a direction perpendicular to the first main surface 10A inside the first electronic components 22. That is, with this configuration, current can be passed to the first wiring portions 12 through the first electronic components 22, and therefore there is no need to design wiring patterns to avoid the first electronic components 22, and the complexity of the wiring patterns can be reduced.

(2-3) In the Second Embodiment, the maximum dimension of each through wiring 23 in a direction parallel to the first main surface 10A is smaller than the maximum dimension of each first via wiring 24 in a direction parallel to the first main surface 10A. With this configuration, a larger current can be passed through the first via wirings 24 than through the through wirings 23. That is, a larger current can be supplied to the first component layer PT1 than would be the case if the maximum dimension of each first via wiring 24 in a direction parallel to the first main surface 10A and the maximum dimension of each through wiring 23 in a direction parallel to the first main surface 10A were the same.

(2-4) In the Second Embodiment, the volume fraction of inorganic material in the passive component 42B is 80 vol % or more. Furthermore, the volume fraction of inorganic material in the entire semiconductor package 10 is 90 vol % or more. With this configuration, the coefficient of thermal expansion can be made uniform throughout the entire semiconductor package 10. Therefore, localized thermal deformation in the semiconductor package 10 can be suppressed.

(2-5) In the Second Embodiment, the first component outer terminals 25 are connected to the second component outer terminals 43 without any other members therebetween. In other words, the second component layer PT2 is connected to the first component layer PT1 without any other wirings such as vias therebetween. Therefore, when a current flows from the first component layer PT1 to the second component layer PT2, it is possible to suppress an increase in DC resistance at the interface between these components.

(2-6) In the Second Embodiment, the maximum dimension of the passive component 42B in a direction perpendicular to the first main surface 10A is greater than the sum of the maximum dimension of the first active component 42A1 in a direction perpendicular to the first main surface 10A and the maximum dimension of the second active component 42A2 in a direction perpendicular to the first main surface 10A. With this configuration, for example, if the passive component 42B is an inductor, the capacity of the core can be secured. Therefore, the obtainable inductance can be increased. Furthermore, with this configuration, even if a capacitor is used as the passive component, the capacitance can be increased.

### Modifications

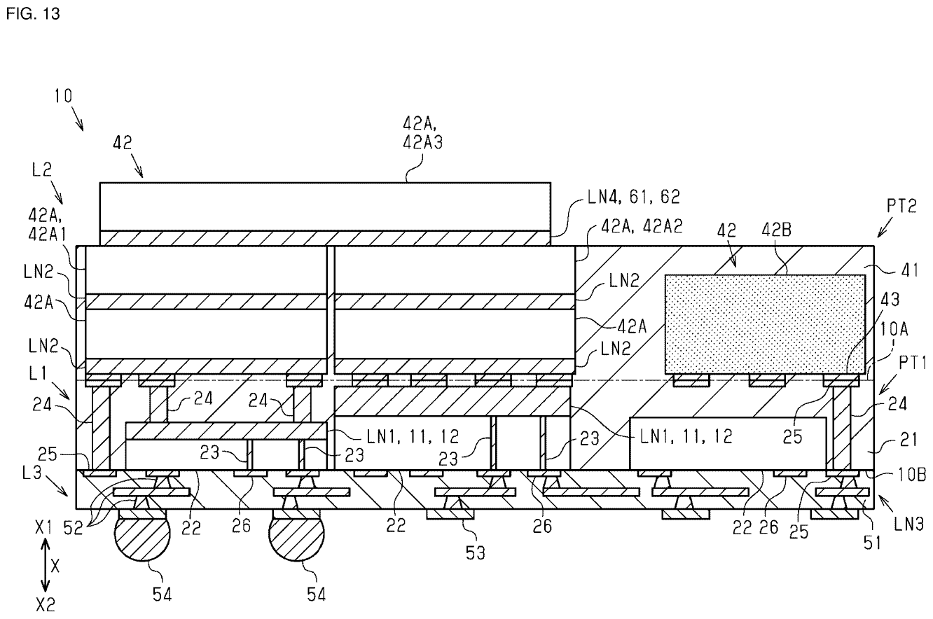

The first and Second Embodiments described above can be implemented with the following modifications. The first and Second Embodiments and the following modifications can be combined to the extent that no technical inconsistencies arise. Note that, hereinafter, in the modifications illustrated in FIGS. 13 to 15, descriptions of parts having substantially the same configurations as in the first and Second Embodiments may be omitted or simplified. In FIGS. 13 to 15, some reference symbols may be omitted for parts having the substantially the same configurations as in the first and Second Embodiments.

In the Second Embodiment, a wiring layer may be further stacked on the first component layer PT1. For example, in the example illustrated in FIG. 13, the semiconductor package 10 includes a third layer L3. The third layer L3 is stacked on the first negative direction X2 side of the first layer L1. In other words, the third layer L3 is directly stacked on the second main surface 10B of the first layer L1. Therefore, the third layer L3 is adjacent to the first component layer PT1 in a direction perpendicular to the first main surface 10A.

The third layer L3 includes a third insulating resin portion 51, third wiring portions 52, and a plurality of third outer wiring terminals 53. Therefore, the third layer L3 is a third wiring layer LN3 including the third wiring portions 52. The third wiring layer LN3 has substantially the same configuration as the second wiring layer in the First Embodiment.

The outer shape of the third insulating resin portion 51 is a substantially rectangular parallelepiped shape. The material of the third insulating resin portion 51 is solely organic resin. The third insulating resin portion 51 covers the peripheral surfaces of the first component outer terminals 25 and the connection terminals 26 that protrude from the first sealing portion 21.

The third wiring portions 52 are connected to the first component outer terminals 25 or the connection terminals 26. The third wiring portions 52 extend inside the third insulating resin portion 51 in an arbitrary pattern. The material of the third wiring portions 52 is the same as the material of the first wiring portions 12. That is, the volume fraction of Cu in the third wiring portions 52 is 50 vol % or more.

A plurality of third wiring outer terminals 53 protrude from the third insulating resin portion 51. Specifically, a plurality of third wiring outer terminals 53 are exposed from the first negative direction X2 side of the third insulating resin portion 51. The material of each third wiring outer terminal 53 has a three-layer structure consisting of a layer having Cu as a main component, a layer having Ni as a main component, and a layer having Au as a main component, from the first positive direction X1 side.

If the third insulating resin portion 51 is composed solely of an inorganic material, a high degree of cleanliness is required in the manufacturing environment of the semiconductor package 10. In the example illustrated in FIG. 13, the material of the third insulating resin portion 51 is solely organic resin. Therefore, in the example illustrated in FIG. 13, a high degree of cleanliness in the manufacturing environment is not required compared to the case where the third insulating resin portion 51 is composed solely of an inorganic material, and an increase in manufacturing costs can be suppressed. It should be noted that the same or a similar effect is achieved not only when the third insulating resin portion 51 is composed solely of organic resin, but also when the third insulating resin portion 51 is composed of an organic resin containing inorganic filler.

In the Second Embodiment, the semiconductor package 10 may further include components for connecting to a motherboard. In the example illustrated in FIG. 13, the semiconductor package 10 includes land portions 54. The land portions 54 are composed of a conductive material such as solder. The land portions 54 are applied to some of the third wiring outer terminals 53. The land portions 54 cover the surfaces of the third wiring outer terminals 53 on the first negative direction X2 side. That is, the land portions 54 are located on the third wiring outer terminals 53 located on the surface of the third wiring layer LN3 facing away from the first component layer PT1 in a direction perpendicular to the first main surface 10A. The land portions 54 are components for connecting to a motherboard mounted on the third wiring layer LN3.

With this configuration, the presence of the land portions 54 allows the wiring patterns of the third wiring portions 52 to be designed to any desired patterns. In other words, the wiring patterns of the third wiring portions 52 can be designed to be suitable patterns taking into consideration the connection between the motherboard and the first electronic components 22 in the first component layer PT1.

In the Second Embodiment, the active components 42A stacked on the first component layer PT1 do not all need to have the same size. In the example illustrated in FIG. 13, the first positive direction X1 surfaces of the two active components 42A located furthermost in the first positive direction X1 among the active components 42A of the second component layer PT2 are exposed from the second sealing portion 41. Here, the two active components 42A in the example illustrated in FIG. 13 are referred to as the first active component 42A1 and the second active component 42A2, respectively. The first active component 42A1 and the second active component 42A2 are stacked on the first component layer PT1 in a direction perpendicular to the first main surface 10A. In the example illustrated in FIG. 13, the first active component 42A1 and the second active component 42A2 are stacked on the first component layer PT1 with the second wiring layers LN2 and other active components 42A interposed therebetween. The first active component 42A1 and the second active component 42A2 are arranged in a direction parallel to the first main surface 10A, without any other electronic components therebetween.

Furthermore, in the example illustrated in FIG. 13, the semiconductor package 10 includes a third active component 42A3 and a fourth wiring layer LN4. The configuration of the fourth wiring layer LN4 is substantially the same as that of the second wiring layer LN2 in the Second Embodiment. That is, the fourth wiring layer LN4 includes a fourth insulating resin portion 61 and fourth wiring portions 62. The fourth wiring portions 62 extend in an arbitrary pattern inside the fourth insulating resin portion 61.

In the example illustrated in FIG. 13, the fourth wiring layer LN4 and the third active component 42A3 are stacked with respect to the first component layer PT1 in a direction perpendicular to the first main surface 10A. Specifically, the third active component 42A3 is stacked on the first active component 42A1 and the second active component 42A2 with the fourth wiring layer LN4 therebetween in a direction perpendicular to the first main surface 10A. No other electronic components are interposed between the third active component 42A3 and the first active component 42A1 and the second active component 42A2. When viewed in a direction perpendicular to the first main surface 10A, the third active component 42A3 and the fourth wiring layer LN4 overlap the first active component 42A1 and the second active component 42A2. With this configuration, power is supplied to the third active component 42A3 via the first active component 42A1 and the second active component 42A2. In other words, the semiconductor package 10 includes highly integrated active components 42A.

In the Second Embodiment, a wiring layer may be stacked on the first component layer PT1 in the first positive direction X1. Alternatively, a plurality of wiring layers may be stacked on the first component layer PT1.

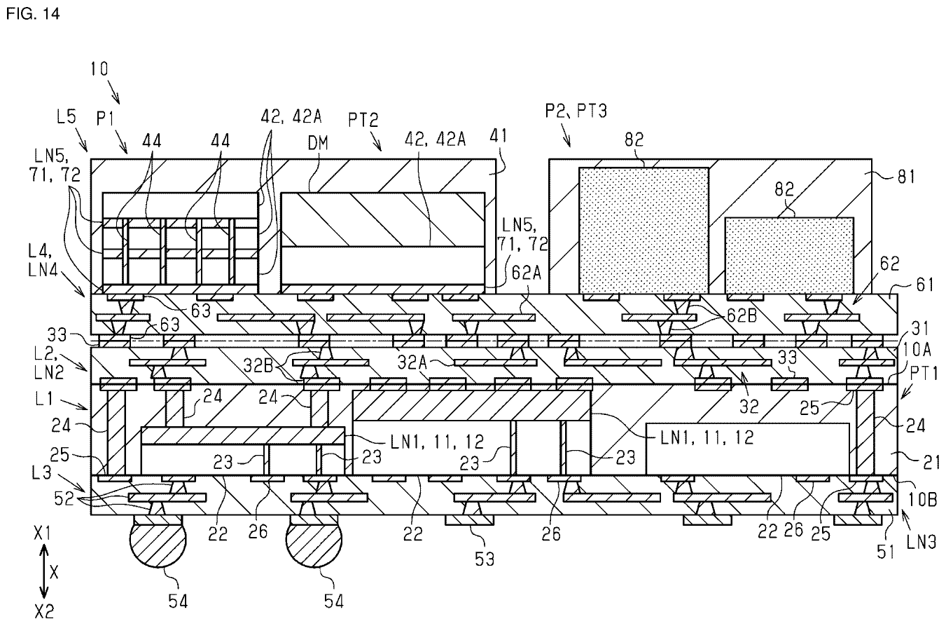

In the example illustrated in FIG. 14, the second layer L2 in the Second Embodiment consists only of the second wiring layer LN2. Also, in the example illustrated in FIG. 14, the semiconductor package 10 includes the fourth layer L4 stacked on the second layer L2 in the first positive direction X1. The fourth layer L4 consists only of the fourth wiring layer LN4. Note that in the example illustrated in FIG. 14, the semiconductor package 10 includes the third wiring layer LN3 similar to the example illustrated in FIG. 13.

The second wiring layer LN2 includes the second insulating resin portion 31, the second wiring portions 32, and a plurality of second wiring outer terminals 33.

The outer shape of the second insulating resin portion 31 is a substantially rectangular parallelepiped shape. The material of the second insulating resin portion 31 is an organic resin containing an inorganic filler. The second wiring portions 32 include a plurality of second columnar wirings 32B extending in a direction intersecting the first main surface 10A, and a plurality of second wirings 32A extending in a direction parallel to the first main surface 10A. Each second wiring 32A is connected to a corresponding second columnar wiring 32B. Each second columnar wiring 32B has an approximately truncated cone shape. The diameter of each second columnar wiring 32B decreases with progress along the first positive direction X1. That is, the maximum dimension of each second columnar wiring 32B in a direction parallel to the first main surface 10A decreases as the second columnar wiring 32B approaches the fourth wiring layer LN4.

The second wiring portions 32 extend within the second insulating resin portion 31 in an arbitrary pattern. The material of the second wiring portions 32 is the same as the material of the first wiring portions 12. That is, the volume fraction of Cu in the second wiring portions 32 is 50 vol % or more.

In the cross-section illustrated in FIG. 14, the second wiring layer LN2 includes 21 second wiring outer terminals 33. The material of each second wiring outer terminal 33 is the same as the material of the second wiring portions 32. Ten of these second wiring outer terminals 33 are located on the first negative direction X2 side of the second wiring portions 32. The peripheral surfaces of these ten second wiring outer terminals 33 are covered by the second insulating resin portion 31. These ten second wiring outer terminals 33 are exposed at the first negative direction X2 side of the second insulating resin portion 31. These ten second wiring outer terminals 33 are connected to the first component outer terminals 25 without any other members therebetween.

The remaining 11 second wiring outer terminals 33 are located on the first positive direction X1 side of the second wiring portions 32. These 11 second wiring outer terminals 33 are exposed on the first negative direction X2 side of the second insulating resin portion 31. Specifically, these 11 second wiring outer terminals 33 protrude in the first positive direction X1 from the second insulating resin portion 31. That is, the second wiring outer terminals 33 protrude from the surface of the second insulating resin portion 31 on the fourth wiring layer LN4 side. The peripheral surfaces of these 11 second wiring outer terminals 33 are not covered by any other material.

In the example illustrated in FIG. 14, as described above, the fourth layer L4 consists only of the fourth wiring layer LN4. The fourth wiring layer LN4 includes the fourth insulating resin portion 61, the fourth wiring portions 62, and a plurality of fourth outer wiring terminals 63.

The outer shape of the fourth insulating resin portion 61 is a substantially rectangular parallelepiped shape. The material of the fourth insulating resin portion 61 is an organic resin containing an inorganic filler. The fourth wiring portions 62 include a plurality of fourth columnar wirings 62B extending in a direction intersecting the first main surface 10A, and a plurality of fourth wirings 62A extending in a direction parallel to the first main surface 10A. Each fourth wiring 62A is connected to a corresponding fourth columnar wiring 62B. Each fourth columnar wiring 62B has an approximately truncated cone shape. The diameter of each fourth columnar wiring 62B decreases with progress in the first negative direction X2. That is, the maximum dimension of each fourth columnar wiring 62B in a direction parallel to the first main surface 10A decreases as the fourth columnar wiring 62B approaches the second wiring layer LN2.

In the cross-section illustrated in FIG. 14, the fourth wiring layer LN4 includes 20 fourth wiring outer terminals 63. The material of each fourth wiring outer terminal 63 is the same as the material of the fourth wiring portions 62. Nine of these fourth wiring outer terminals 63 are located on the first positive direction X1 side of the fourth wiring portions 62. The peripheral surfaces of these nine fourth wiring outer terminals 63 are covered by the second insulating resin portion 31. These nine fourth wiring outer terminals 63 are exposed at the first positive direction X1 side of the fourth insulating resin portion 61.

The remaining 11 fourth outer wiring terminals 63 are located on the first negative direction X2 side of the fourth wiring portions 62. These 11 fourth outer wiring terminals 63 are exposed on the first negative direction X2 side of the second insulating resin portion 31. Specifically, these 11 fourth outer wiring terminals 63 protrude in the first negative direction X2 from the fourth insulating resin portion 61. That is, the fourth outer wiring terminals 63 protrude from the surface of the fourth insulating resin portion 61 on the second wiring layer LN2 side. The peripheral surfaces of these 11 fourth outer wiring terminals 63 are not covered by other members. These fourth outer wiring terminals 63 are connected to the second wiring outer terminals 33. The peripheral surfaces of the fourth outer wiring terminals 63 and the second wiring outer terminals 33 are not covered by other members. Therefore, gaps are created between the second insulating resin portion 31 and the fourth insulating resin portion 61.

In the example illustrated in FIG. 14, a gap is created between the second insulating resin portion 31 and the fourth insulating resin portion 61. With this configuration, even if bending stress is generated in the entire semiconductor package 10, the stress can be dissipated by this gap. In other words, with this configuration, it is possible to suppress the occurrence of cracks or other damage in the semiconductor package 10 caused by bending stress generated in the semiconductor package 10.

Furthermore, in the example illustrated in FIG. 14, the maximum dimension of each second columnar wiring 32B in a direction parallel to the first main surface 10A decreases as the second columnar wiring 32B approaches the fourth wiring layer LN4. Similarly, the maximum dimension of each fourth columnar wiring 62B in a direction parallel to the first main surface 10A decreases as the fourth columnar wiring 62B approaches the second wiring layer LN2. In other words, the shapes of the second columnar wiring 32B and the fourth columnar wiring 62B are reversed in a direction along the first axis X. If the second wiring layers LN2 and the fourth wiring layer LN4 are manufactured using the same process, the second columnar wirings 32B and the fourth columnar wirings 62B will have similar tapered shapes. On the other hand, if the second wiring layers LN2 and the fourth wiring layer LN4 are formed and then stacked on top of each other, the shapes of each columnar wiring can be reversed between the second wiring layer LN2 and the fourth wiring layer LN4. According to the above configuration, it is also possible to form wiring layers in parallel. In other words, by forming wiring layers in parallel, it is possible to shorten the manufacturing time.

In the Second Embodiment, the second component layer PT2 does not have to cover the entirety of an adjacent layer. In the example illustrated in FIG. 14, the semiconductor package 10 includes the fifth layer L5 stacked on the first positive direction X1 side of the fourth layer L4. The fifth layer L5 includes a first part P1 and a second part P2.

The first part P1 includes the second component layer PT2, four fifth wiring layers LN5, and a dummy portion DM. In the first part P1, the fifth wiring layers LN5, which are separate layers from the second component layer PT2, are embedded inside the second component layer PT2.

The second component layer PT2 includes the second sealing portion 41 and a plurality of second electronic components 42. The outer shape of the second sealing portion 41 is a substantially rectangular parallelepiped shape. The four fifth wiring layers LN5 described above are located inside the second sealing portion 41. That is, the fifth wiring layers LN5 are adjacent to the second sealing portion 41 or the second electronic components 42, which are part of the second component layer PT2, in a direction perpendicular to the first main surface 10A. The material of the second sealing portion 41 is a synthetic resin containing an inorganic filler. In the example illustrated in FIG. 14, the inorganic filler is silica. That is, the second sealing portion 41 contains an inorganic material.

In the example illustrated in FIG. 14, the second component layer PT2 includes four second electronic components 42. All of the second electronic components 42 are active components 42A. Each active component 42A is located inside the second sealing portion 41.

Two of the four second electronic components 42 are arranged in a direction parallel to the first main surface 10A. A fifth wiring layer LN5 is stacked on the surface of each of these two second electronic components 42 on the first negative direction X2 side. Furthermore, on the surface of one active component 42A on the first positive direction X1 side, there is a multilayer body consisting of a total of six elements, with the fifth wiring layer LN5, another second electronic component 42, the fifth wiring layer LN5, and another second electronic component 42 stacked in this order. In this multilayer body, the adjacent fifth wiring layers LN5 and second electronic components 42 are electrically connected to each other. However, each fifth wiring layer LN5 is not electrically connected to the other fifth wiring layers LN5 within the first part P1.

Two of the three second electronic components 42 included in this multilayer body include four through wirings 44. Specifically, two of the three stacked second electronic components 42, starting from the first negative direction X2 side, include four through wirings 44. The four through wirings 44 are arranged in a direction parallel to the first main surface 10A. Each through wiring 44 penetrates through the corresponding second electronic component 42 in a direction perpendicular to the first main surface 10A. Furthermore, each through wiring 44 also penetrates through the fifth wiring layers LN5, which are stacked on the first positive direction X1 side of the second electronic components 42, in a direction perpendicular to the first main surface 10A. The through wirings 44 of each second electronic component 42 are connected to each other. In other words, in the multilayer body, each through wiring 44 electrically connects the fifth wiring layer LN5, located furthest toward the first negative direction X2 side, to the second electronic component 42 located furthest toward the first positive direction X1 side.

In the example illustrated in FIG. 14, the dummy portion DM is located on the first positive direction X1 side of the remaining unstacked second electronic component 42 among the four second electronic components 42. The dummy portion DM directly covers the entire surface of the second electronic component 42 on the first positive direction X1 side. The dummy portion DM is composed of a thermally conductive synthetic resin. The dummy portion DM can efficiently absorb heat from the second electronic component 42 and dissipate the absorbed heat to the outside.

Each fifth wiring layer LN5 includes fifth wiring portions 72 and a fifth insulating resin portion 71. Note that in FIG. 14, the fifth wiring portions 72 and the fifth insulating resin portion 71 inside each fifth wiring layer LN5 are not illustrated. The fifth wiring portions 72 and the fifth insulating resin portion 71 have the same configuration as those in the first wiring layer LN1. That is, the outer shape of each fifth insulating resin portion 71 is a substantially rectangular parallelepiped shape. However, the dimension of each fifth insulating resin portion 71 in a direction parallel to the first main surface 10A is smaller than the dimension of the first part P1 in a direction parallel to the first main surface 10A. Also, the dimension of each fifth insulating resin portion 71 in a direction perpendicular to the first main surface 10A is smaller than the dimension of the first part P1 in a direction perpendicular to the first main surface 10A. The material of each fifth insulating resin portion 71 is a synthetic resin containing an inorganic filler.

Each fifth wiring portion 72 extends inside the corresponding fifth insulating resin portion 71 in an arbitrary pattern. The material of each fifth wiring portion 72 is the same as the material of the first wiring portions 12. That is, the volume fraction of Cu in the fifth wiring portions 72 is 50 vol % or more.

The second part P2 is located spaced apart from the first part P1 in a direction parallel to the first main surface 10A. The second part P2 consists only of a third component layer PT3. The third component layer PT3 includes a third sealing portion 81 and a plurality of third electronic components 82.

The outer shape of third sealing portion 81 is a substantially rectangular parallelepiped shape. The material of the third sealing portion 81 is a synthetic resin containing an inorganic filler. However, the third sealing portion 81 contains a inorganic filler different from that in the second sealing portion 41. The third sealing portion 81 contains a magnetic metal filler containing the element Fe. In other words, the material of the second sealing portion 41 is different from the material of the third sealing portion 81. Note that “different materials” includes not only cases where the compositions of the second sealing portion 41 and the third sealing portion 81 are different, but also cases where the particle size of the inorganic filler contained in the materials are different.

In the example illustrated in FIG. 14, the third component layer PT3 includes two third electronic components 82. Each third electronic component 82 is located inside the third sealing portion 81. Both of the third electronic components 82 are passive components. The two third electronic components 82 are arranged in a direction parallel to the first main surface 10A.

As described above, the second component layer PT2 and the third component layer PT3 are stacked on the first component layer PT1 with the fourth wiring layer LN4 therebetween in a direction perpendicular to the first main surface 10A. Furthermore, the second component layer PT2 and the third component layer PT3 are arranged on the fourth wiring layer LN4 in a direction parallel to the first main surface 10A. In other words, the second component layer PT2 and the third component layer PT3 are located at the same location in a direction perpendicular to the first main surface 10A.

In the example illustrated in FIG. 14, the second component layer PT2 and the third component layer PT3 are located in the same layer in a direction perpendicular to the first main surface 10A. That is, the second component layer PT2 and the third component layer PT3 can be formed at similar timings. In other words, this configuration allows for high-density mounting at low cost without the manufacturing process becoming complex.

Furthermore, in the example illustrated in FIG. 14, the material of the second sealing portion 41 and the material of the third sealing portion 81 are different from each other. The material of the second sealing portion 41 can be selected to suit an active component. The material of the third sealing portion 81 can be selected to suit a passive component. In other words, with the above configuration, a suitable material can be selected for each electronic component. In particular, as mentioned above, by using a magnetic metal filler containing the element Fe in the third sealing portion 81, the inductance of a passive component can be improved, emission of noise can be suppressed, and heat dissipation can be enhanced.

In the example illustrated in FIG. 14, the shape of the second columnar wirings 32B and the shape of the fourth columnar wirings 62B may be substantially the same. That is, both the second columnar wirings 32B and the fourth columnar wirings 62B may have a diameter that decreases as they approach the first negative direction X2 side, or their diameters may decrease as they approach the first positive direction X1 side.

In the example illustrated in FIG. 14, the material of the second sealing portion 41 and the material of the third sealing portion 81 may be the same.

In the example illustrated in FIG. 14, the first part P1 does not have to include the fifth wiring layer LN5.

In the example illustrated in FIG. 14, the first part P1 does not have to include the dummy portion DM. Furthermore, other component layers may include the dummy portion DM. The same applies to the component layers in the first and Second Embodiments.

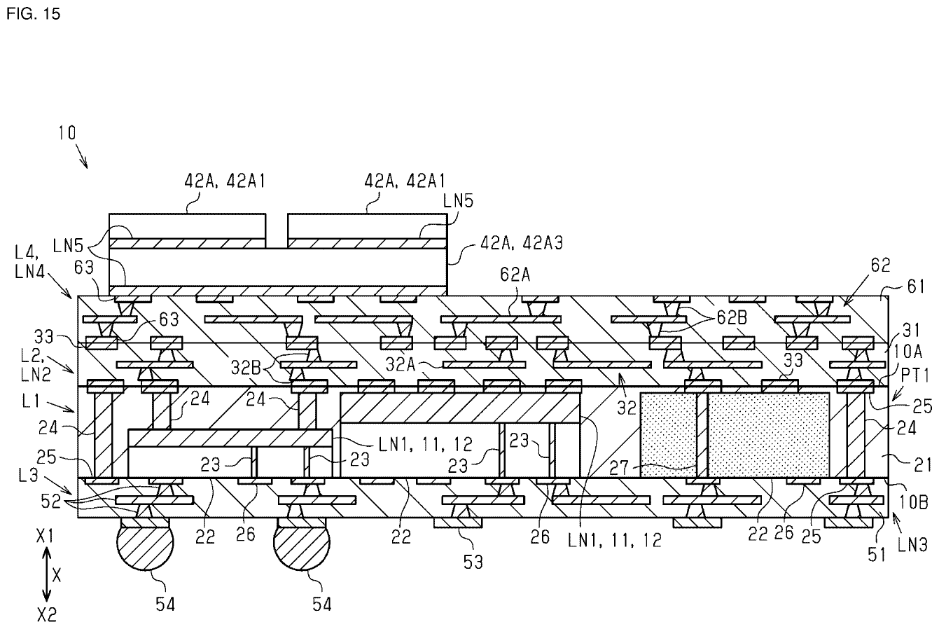

In the example illustrated in FIG. 14, a gap does not need to be present between the second insulating resin portion 31 and the fourth insulating resin portion 61. In the example illustrated in FIG. 15, some of the second wiring outer terminals 33 are exposed from the surface of the second insulating resin portion 31 on the fourth wiring layer LN4 side. The peripheral surfaces of the second wiring outer terminals 33 is covered by the second insulating resin portion 31. Also, some of the fourth outer wiring terminals 63 are exposed from the surface of the fourth insulating resin portion 61 on the second wiring layer LN2 side. The peripheral surfaces of the fourth outer wiring terminals 63 are covered by the fourth insulating resin portion 61. The fourth outer wiring terminals 63 are connected to the second wiring outer terminals 33. The peripheral surfaces of the fourth outer wiring terminals 63 and the second wiring outer terminals 33 are covered by the second insulating resin portion 31 and the fourth insulating resin portion 61, respectively. That is, the peripheral surfaces of the fourth outer wiring terminals 63 and the second wiring outer terminals 33 are covered with synthetic resin. In the example illustrated in FIG. 15, the second insulating resin portion 31 and the fourth insulating resin portion 61 are in contact with each other.

In the configuration of the example illustrated in FIG. 15, the connection between the second wiring layer LN2 and the fourth wiring layer LN4 is made not only by the outer terminals but also by synthetic resin. As a result, the adhesion between the second wiring layer LN2 and the fourth wiring layer LN4 is improved.

In the example illustrated in FIG. 15, the synthetic resin covering the second wiring outer terminals 33 and the peripheral surfaces of the second wiring outer terminals 33 are not limited to the second insulating resin portion 31 and the fourth insulating resin portion 61. For example, the second wiring outer terminals 33 and the second wiring outer terminals 33 may be covered with a synthetic resin such as underfill.

In the example illustrated in FIG. 13, the third active component 42A3 may be located on the first negative direction X2 side relative to the first active component 42A1 and the second active component 42A2. For example, in the example illustrated in FIG. 15, the third active component 42A3 is stacked on the fourth wiring layer LN4 with the fifth wiring layer LN5 therebetween. The first active component 42A1 is stacked on the first positive direction X1 side of the third active component 42A3 with the corresponding fifth wiring layer LN5 therebetween. The second active component 42A2 is also stacked on the first positive direction X1 side of the third active component 42A3 with the corresponding fifth wiring layer LN5 therebetween. The first active component 42A1 and the second active component 42A2 are arranged in a direction parallel to the first main surface 10A. In other words, as illustrated in the example in FIG. 15, a plurality of active components 42A may be stacked in a direction parallel to the first main surface 10A relative to one active component 42A.

In the Second Embodiment, a passive component 22B may include a through wiring 27. In the example illustrated in FIG. 15, at least one of the first electronic components 22 is a passive component 22B. The passive component 22B includes a through wiring 27. The through wiring 27 penetrates through the passive component 22B in a direction perpendicular to the first main surface 10A. The through wiring 27 has a substantially cylindrical shape. The maximum dimension of the through wiring 27 in a direction parallel to the first main surface 10A is smaller than the maximum dimension of the first via wirings 24 in a direction parallel to the first main surface 10A. Also, the maximum dimension of the through wiring 27 in the passive component 22B in a direction parallel to the first main surface 10A is larger than the maximum dimension of the through wiring 23 in an active component 22A in a direction parallel to the first main surface 10A.

In the example illustrated in FIG. 15, the maximum dimension of the through wiring 27 in the passive component 22B in a direction parallel to the first main surface 10A may be the same as or larger than the maximum dimension of the first via wirings 24 in a direction parallel to the first main surface 10A. Also, the maximum dimension of the through wiring 27 in the passive component 22B in a direction parallel to the first main surface 10A may be the same as or smaller than the maximum dimension of the through wirings 23 in the active component 22A in a direction parallel to the first main surface 10A.

In the First Embodiment, the connection terminals 13 of the first electronic components 12 may have a multilayer structure. For example, the connection terminals 13 may include layers mainly composed of Ni, Sn, Au, etc. However, in order to achieve the effects described in (1-4) above, it is preferable that the volume fraction of Cu at the outer surface of each connection terminal 13 be 50 vol % or more. Alternatively, the volume fraction of Cu at the outer surface of the connection terminals 13 may be less than 50 vol %.

In the First Embodiment, the volume fraction of Cu in the first wiring portions 22 may be less than 50 vol %. Alternatively, Ag, Al, and Au may be used instead of Cu in the first wiring portions 22. The same applies to the wiring portions of each wiring layer. The same also applies to the wiring portions of each wiring layer in the Second Embodiment.

In the First Embodiment, the shape of the first columnar wirings 22B is not limited to a truncated cone shape. For example, a cylindrical or prismatic shape may be used. The same applies to other columnar wirings.

In the First Embodiment, it is sufficient that the first component layer includes at least one active component. It is sufficient that the semiconductor package 10 includes at least one passive component and one active component. The same applies to the Second Embodiment.

In the First Embodiment, it is sufficient that the first component layer includes at least one first via wiring 14. Furthermore, if the first component layer includes the first via wirings 14, other component layers do not need to include via wirings. The same applies to the component layers in the Second Embodiment.

In the First Embodiment, the maximum dimension of the passive component 12B in a direction perpendicular to the first main surface 10A may be the same as or smaller than the maximum dimension of each active component 12A in a direction perpendicular to the first main surface 10A.

In the First Embodiment, the volume fraction of inorganic material in the passive component 12B is not limited to the example in the First Embodiment. That is, the volume fraction of inorganic material in the passive component 12B may be less than 50 vol %. The same applies to other passive components. The same also applies to the passive component 42B in the Second Embodiment.

In the First Embodiment, the amount of protrusion of the connection terminals 13 may be less than the amount of protrusion of the inner terminals 13A. Also, the inner terminals 13A may protrude in the first positive direction X1 from the surface of the component body 12M on the first positive direction X1 side, or the inner terminals 13A may be recessed on the first negative direction X2 side.

In the Second Embodiment, the ends of the through wirings 23 on the first positive direction X1 side may be connected to the first via wirings 24. That is, the through wirings 23 may be directly connected to the first via wirings 24 without the intermediary of the first wiring portions 12. Also, if the first positive direction X1 side of the first electronic components 22 faces the first component outer terminals 25, the ends of the through wirings 23 on the first positive direction X1 side may be connected to the first component outer terminals 25. Furthermore, in the Second Embodiment, the first electronic components 22 do not have to include the through wirings 23. Also, the second electronic components 42 may include through wirings.

In the Second Embodiment, the dimensional relationship between the through wirings 23 and the first via wirings 24 is not limited to that in the Second Embodiment. The maximum dimension of each through wiring 23 in a direction parallel to the first main surface 10A may be the same as or greater than the maximum dimension of each first via wiring 24 in a direction parallel to the first main surface 10A.

In the Second Embodiment, the positions of the first wiring layers LN1 are not limited to those in the example in the Second Embodiment as long as the first wiring layers LN1 are adjacent to the first component layer PT1 in a direction perpendicular to the first main surface 10A. For example, the first wiring layers LN1 may be stacked on the first negative direction X2 side with respect to the first electronic components 22.

In the Second Embodiment, the volume ratio of inorganic material in the entire semiconductor package 10 may be less than 90 vol %.

In the Second Embodiment, the dimensional relationship between the active components 42A and the passive component 42B among the second electronic components 42 is not limited to the example in the Second Embodiment. For example, the maximum dimension of the passive component 42B in a direction perpendicular to the first main surface 10A may be the same as or smaller than the sum of the maximum dimension of the first active component 42A1 in a direction perpendicular to the first main surface 10A and the maximum dimension of the second active component 42A2 in a direction perpendicular to the first main surface 10A.

In the Second Embodiment, other wiring layers may be located between the first layer L1 and the second layer L2. That is, other members may be interposed between the first component outer terminals 25 and the second component outer terminals 43.

### Appendices

Technical concepts that can be derived from the above embodiments and modifications are described below.
[1] A semiconductor package including a passive component and an active component. The semiconductor package comprises a first component layer having a first main surface and a second main surface on an opposite side from the first main surface; and a first wiring layer adjacent to the first component layer in a direction perpendicular to the first main surface. The first component layer includes a first sealing portion containing an inorganic material, at least one of the active component located inside the first sealing portion, and a plurality of first via wirings extending inside the first sealing portion in a direction intersecting the first main surface, with end portions thereof exposed from the first sealing portion at the first main surface. The first wiring layer includes a first insulating resin portion and a first wiring portion extending inside the first insulating resin portion, and a connection terminal of the active component is exposed from the first sealing portion at a side of the first sealing portion where the second main surface is located.
[2] The semiconductor package according to [1], wherein the first wiring layer is stacked on the first main surface or the second main surface of the first component layer.
[3] The semiconductor package according to [2], wherein the first wiring layer is stacked on the first main surface of the first component layer, first ends of the first via wirings are connected to the active component, and second ends of the first via wirings are connected to the first wiring portion in the first wiring layer.
[4] The semiconductor package according to [2] or [3], wherein the first wiring layer includes a first wiring outer terminal on a surface facing away from the first component layer in a direction perpendicular to the first main surface, and a land portion for connecting a mother board mounted on the first wiring layer is provided on the first wiring outer terminal.
[5] The semiconductor package according to [2] or [3], comprising a second wiring layer stacked on the first wiring layer in a direction perpendicular to the first main surface. The second wiring layer includes a second insulating resin portion and a second wiring portion extending inside the second insulating resin portion, the first wiring layer includes a first wiring outer terminal protruding from a surface of the first insulating resin portion on a side where the second wiring layer is located, the second wiring layer includes a second wiring outer terminal protruding from a surface of the second insulating resin portion on a side where the first wiring layer is located and connected to the first wiring outer terminal, and a gap is formed between the first insulating resin portion and the second insulating resin portion.
[6] The semiconductor package according to [2] or [3], comprising a second wiring layer stacked on the first wiring layer in a direction perpendicular to the first main surface, wherein the second wiring layer includes a second insulating resin portion and a second wiring portion extending inside the second insulating resin portion, the first wiring layer includes a first wiring outer terminal exposed from a surface of the first insulating resin portion on a side where the second wiring layer is located, the second wiring layer includes a second wiring outer terminal exposed from a surface of the second insulating resin portion on a side where the first wiring layer is located and connected to the first wiring outer terminal, and peripheral surfaces of the first wiring outer terminal and the second wiring outer terminal are covered with a synthetic resin.
[7] The semiconductor package according to [5] or [6], wherein the first wiring portion includes a first columnar wiring extending in a direction intersecting the first main surface and a first wiring connected to the first columnar wiring and extending in a direction parallel to the first main surface. A maximum dimension of the first columnar wiring in a direction parallel to the first main surface decreases as the first columnar wiring approaches the second wiring layer. The second wiring portion includes a second columnar wiring extending in a direction intersecting the first main surface and a second wiring connected to the second columnar wiring and extending in a direction parallel to the first main surface, and a maximum dimension of the second columnar wiring in a direction parallel to the first main surface decreases as the second columnar wiring approaches the first wiring layer.
[8] The semiconductor package according to any one of [1] to [7], wherein the first insulating resin portion is composed of an organic resin.
[9] The semiconductor package according to any one of [1] to [8], wherein a volume fraction of Cu at an outer surface of the connection terminal of the active component located inside the first sealing portion is 50 vol % or more, and a volume fraction of Cu in the first wiring portion is 50 vol % or more.
[10] The semiconductor package according to any one of [1] to [9], wherein one or more selected from the active components located inside the first sealing portion include a through wiring that penetrates through the active component in a direction perpendicular to the first main surface, and the through wiring is connected to the first wiring portion or the first via wiring.
[11] The semiconductor package according to [10], wherein a maximum dimension of the through wiring in a direction parallel to the first main surface is smaller than a maximum dimension of the first via wiring in a direction parallel to the first main surface.
[12] The semiconductor package according to any one of [1] to [11], wherein the passive component contains an inorganic material, and a volume fraction of the inorganic material in the passive component is 50 vol % or more.
[13] The semiconductor package according to [12], wherein the volume fraction of the inorganic material in the passive component is 80 vol % or more, and the volume fraction of the inorganic material in the entire semiconductor package is 90 vol % or more.
[14] The semiconductor package according to any one of [1] to [13], wherein a maximum dimension of the passive component in a direction perpendicular to the first main surface is greater than a maximum dimension of the active component in a direction perpendicular to the first main surface.
[15] The semiconductor package according to any one of [1] to [14], comprising a second component layer stacked on the first component layer in a direction perpendicular to the first main surface. The second component layer includes a second sealing portion containing an inorganic material, at least one of the active component located inside the second sealing portion, and a second component outer terminal exposed from a surface of the second sealing portion on a side where the first component layer is located. The first component layer includes a first component outer terminal exposed from a surface of the first sealing portion on a side where the second component layer is located, and the first component outer terminal is connected to the second component outer terminal without any other member therebetween.
[16] The semiconductor package according to any one of [1] to [15], comprising a first active component, a second active component, and a third active component stacked on the first component layer in a direction perpendicular to the first main surface. The first active component and the second active component are arranged in a direction parallel to the first main surface without any other electronic components therebetween. The third active component is stacked on the first active component and the second active component in a direction perpendicular to the first main surface without any other electronic components therebetween, and when viewed in a direction perpendicular to the first main surface, the third active component overlaps the first active component and the second active component.
[17] The semiconductor package according to any one of [1] to [16], comprising a first active component, a second active component, and at least one of the passive component, which are stacked on the first component layer in a direction perpendicular to the first main surface. The first active component and the second active component are stacked on the first component layer in a direction perpendicular to the first main surface without any other electronic components therebetween. A maximum dimension of the passive component in a direction perpendicular to the first main surface is greater than a sum of a maximum dimension of the first active component in a direction perpendicular to the first main surface and a maximum dimension of the second active component in a direction perpendicular to the first main surface.
[18] The semiconductor package according to any one of [1] to [17], comprising a second component layer and a third component layer stacked on the first component layer in a direction perpendicular to the first main surface. The second component layer includes a second sealing portion containing an inorganic material and at least one of the active component located inside the second sealing portion. The third component layer includes a third sealing portion containing an inorganic material and at least one of the passive component located inside the third sealing portion, and the second component layer and the third component layer are located at an identical position in a direction perpendicular to the first main surface.
[19] The semiconductor package according to [18], wherein a material of the second sealing portion is different from a material of the third sealing portion.
[20] The semiconductor package according to any one of [1] to [19], wherein the active component located inside the first sealing portion includes a component body, the connection terminal protruding from the component body, and an inner terminal exposed from the component body on an opposite side from the connection terminal in a direction perpendicular to the first main surface, and an amount of protrusion of the connection terminal is greater than an amount of protrusion of the inner terminal.

What is claimed is:

1. A semiconductor package including a passive component and an active component,
the semiconductor package comprising:
a first component layer having a first main surface and a second main surface on an opposite side from the first main surface; and
a first wiring layer adjacent to the first component layer in a direction perpendicular to the first main surface,
wherein the first component layer includes
a first sealing portion including an inorganic material,
at least one of the active component inside the first sealing portion, and
a plurality of first via wirings extending inside the first sealing portion in a direction intersecting the first main surface, with end portions thereof exposed from the first sealing portion at the first main surface,
the first wiring layer includes
a first insulating resin portion, and
a first wiring portion extending inside the first insulating resin portion, and
a connection terminal of the active component is exposed from the first sealing portion at a side of the first sealing portion where the second main surface is located.

2. The semiconductor package according to claim 1, wherein
the first wiring layer is stacked on the first main surface or the second main surface of the first component layer.

3. The semiconductor package according to claim 2, wherein
the first wiring layer is stacked on the first main surface of the first component layer,
first ends of the first via wirings are connected to the active component, and
second ends of the first via wirings are connected to the first wiring portion in the first wiring layer.

4. The semiconductor package according to claim 2, wherein
the first wiring layer includes a first wiring outer terminal on a surface facing away from the first component layer in a direction perpendicular to the first main surface, and
a land portion for connecting a mother board mounted on the first wiring layer is on the first wiring outer terminal.

5. The semiconductor package according to claim 2, further comprising:
a second wiring layer stacked on the first wiring layer in a direction perpendicular to the first main surface,
wherein the second wiring layer includes
a second insulating resin portion, and
a second wiring portion extending inside the second insulating resin portion,
the first wiring layer includes a first wiring outer terminal protruding from a surface of the first insulating resin portion on a side where the second wiring layer is located,
the second wiring layer includes a second wiring outer terminal protruding from a surface of the second insulating resin portion on a side where the first wiring layer is located and connected to the first wiring outer terminal, and
a gap is between the first insulating resin portion and the second insulating resin portion.

6. The semiconductor package according to claim 2, further comprising:
a second wiring layer stacked on the first wiring layer in a direction perpendicular to the first main surface,
wherein the second wiring layer includes
a second insulating resin portion, and
a second wiring portion extending inside the second insulating resin portion,
the first wiring layer includes a first wiring outer terminal exposed from a surface of the first insulating resin portion on a side where the second wiring layer is located,
the second wiring layer includes a second wiring outer terminal exposed from a surface of the second insulating resin portion on a side where the first wiring layer is located and connected to the first wiring outer terminal, and
peripheral surfaces of the first wiring outer terminal and the second wiring outer terminal are covered with a synthetic resin.

7. The semiconductor package according to claim 5, wherein
the first wiring portion includes a first columnar wiring extending in a direction intersecting the first main surface and a first wiring connected to the first columnar wiring and extending in a direction parallel to the first main surface,
a maximum dimension of the first columnar wiring in a direction parallel to the first main surface decreases as the first columnar wiring approaches the second wiring layer,
the second wiring portion includes a second columnar wiring extending in a direction intersecting the first main surface and a second wiring connected to the second columnar wiring and extending in a direction parallel to the first main surface, and
a maximum dimension of the second columnar wiring in a direction parallel to the first main surface decreases as the second columnar wiring approaches the first wiring layer.

8. The semiconductor package according to claim 1, wherein
the first insulating resin portion includes an organic resin.

9. The semiconductor package according to claim 1, wherein
a volume fraction of Cu at an outer surface of the connection terminal of the active component inside the first sealing portion is 50 vol % or more, and
a volume fraction of Cu in the first wiring portion is 50 vol % or more.

10. The semiconductor package according to claim 1, wherein
one or more selected from the active components inside the first sealing portion includes a through wiring that penetrates through the active component in a direction perpendicular to the first main surface, and
the through wiring is connected to the first wiring portion or the first via wiring.

11. The semiconductor package according to claim 10, wherein
a maximum dimension of the through wiring in a direction parallel to the first main surface is smaller than a maximum dimension of the first via wiring in a direction parallel to the first main surface.

12. The semiconductor package according to claim 1, wherein
the passive component includes an inorganic material, and
a volume fraction of the inorganic material in the passive component is 50 vol % or more.

13. The semiconductor package according to claim 12, wherein
the volume fraction of the inorganic material in the passive component is 80 vol % or more, and
the volume fraction of the inorganic material in the entire semiconductor package is vol % or more.

14. The semiconductor package according to claim 1, wherein
a maximum dimension of the passive component in a direction perpendicular to the first main surface is greater than a maximum dimension of the active component in a direction perpendicular to the first main surface.

15. The semiconductor package according to claim 1, further comprising:
a second component layer stacked on the first component layer in a direction perpendicular to the first main surface,
wherein the second component layer includes
a second sealing portion including an inorganic material,
at least one of the active component inside the second sealing portion, and
a second component outer terminal exposed from a surface of the second sealing portion on a side where the first component layer is located,
the first component layer includes a first component outer terminal exposed from a surface of the first sealing portion on a side where the second component layer is located, and
the first component outer terminal is connected to the second component outer terminal without any other member therebetween.

16. The semiconductor package according to claim 1, further comprising:
a first active component, a second active component, and a third active component stacked on the first component layer in a direction perpendicular to the first main surface,
wherein the first active component and the second active component are arranged in a direction parallel to the first main surface without any other electronic components therebetween,
the third active component is stacked on the first active component and the second active component in a direction perpendicular to the first main surface without any other electronic components therebetween, and
when viewed in a direction perpendicular to the first main surface, the third active component overlaps the first active component and the second active component.

17. The semiconductor package according to claim 1, further comprising:
a first active component, a second active component, and at least one of the passive component, which are stacked on the first component layer in a direction perpendicular to the first main surface,
wherein the first active component and the second active component are stacked on the first component layer in a direction perpendicular to the first main surface without any other electronic components therebetween, and
a maximum dimension of the passive component in a direction perpendicular to the first main surface is greater than a sum of a maximum dimension of the first active component in a direction perpendicular to the first main surface and a maximum dimension of the second active component in a direction perpendicular to the first main surface.

18. The semiconductor package according to claim 1, further comprising:
a second component layer and a third component layer stacked on the first component layer in a direction perpendicular to the first main surface,
wherein the second component layer includes
a second sealing portion including an inorganic material, and
at least one of the active component inside the second sealing portion,
the third component layer includes a third sealing portion including an inorganic material and at least one of the passive component inside the third sealing portion, and
the second component layer and the third component layer are at an identical position in a direction perpendicular to the first main surface.

19. The semiconductor package according to claim 18, wherein
a material of the second sealing portion is different from a material of the third sealing portion.

20. The semiconductor package according to claim 1, wherein
the active component inside the first sealing portion includes
a component body,
the connection terminal protruding from the component body, and
an inner terminal exposed from the component body on an opposite side from the connection terminal in a direction perpendicular to the first main surface, and
an amount of protrusion of the connection terminal is greater than an amount of protrusion of the inner terminal.
